(19) United States
(12) Patent Application Publication
(10) Pub. No.: US 2026/0231397 A1
(43) Pub. Date: Aug. 6, 2026

(54) 3D STACKED SEMICONDUCTOR DEVICE AND MANUFACTURING METHOD THEREFOR, AND ELECTRONIC DEVICE

(71) Applicant: BEIJING SUPERSTRING ACADEMY OF MEMORY TECHNOLOGY, Beijing (CN)

(72) Inventors: Wenhua Gui, Beijing (CN); Shujuan Mao, Beijing (CN); Xiangsheng Wang, Beijing (CN); Jin Dai, Beijing (CN); Xuezheng Ai, Beijing (CN); Wei Yu, Beijing (CN); Guilei Wang, Beijing (CN)

(73) Assignee: BEIJING SUPERSTRING ACADEMY OF MEMORY TECHNOLOGY, Beijing (CN)

(21) Appl. No.: 19/154,960

(22) PCT Filed: Apr. 28, 2023
(86) PCT No.: PCT/CN2023/091886

§ 371 Date: Aug. 8, 2025

(30) Foreign Application Priority Data
Feb. 23, 2023 (CN) 202310162140.8

(51) Int. Cl. H10B 12/00

(52) U.S. Cl. CPC H10B 12/482; H10B 12/05

(57) ABSTRACT

A 3D stacked semiconductor device and a manufacturing method therefor, and an electronic device. The 3D stacked semiconductor device comprises: a plurality of transistors, which are distributed in different layers and are stacked in a direction perpendicular to a substrate. Each transistor comprises: a first electrode; a second electrode; an insulation portion, which connects the first electrode and the second electrode; a semiconductor layer, by which the first electrode, the insulation portion and the second electrode are surrounded; a gate electrode, by which a side wall of the semiconductor layer is surrounded; and a gate insulation layer, which is disposed between the gate electrode and the semiconductor layer, wherein the first electrode, the insulation portion and the second electrode are connected to form an integrated structure.

### CROSS-REFERENCE TO RELATED APPLICATIONS

The present application is a U.S. National Phase Entry of International Application PCT/CN2023/091886 having an international filing date of Apr. 28, 2023, which claims the priority to Chinese patent application No. 2023101621408 filed to the CNIPA on Feb. 23, 2023, entitled “3D Stacked Semiconductor Device and Manufacturing Method Therefor, and Electronic Device”. The entire contents of the above-identified applications are incorporated herein by reference.

### TECHNICAL FIELD

Embodiments of the present disclosure relate to, but are not limited to, the field of semiconductor technologies, in particular to a three-dimensional (3D) stacked semiconductor device, a manufacturing method therefor, and an electronic device.

### BACKGROUND

As Dynamic Random Access Memory (DRAM) technology enters a phase of smaller sizes, a planar 1T1C structure has approached its limit. In terms of obtaining higher capacitance, lower leakage, and higher integration, development of 2D devices at present has been limited. Nowadays, a 3D stack structure of a semiconductor device or chip is a new technical direction to solve a problem of 1T1C storage density.

### SUMMARY

The following is a summary of subject matter described in detail in this document. This summary is not intended to limit the scope of protection of the claims.

An embodiment of the present disclosure provides a 3D stacked semiconductor device, including:
a plurality of transistors distributed in different layers and stacked along a direction perpendicular to a base substrate;
a transistor of the plurality of transistors includes a first electrode, a second electrode, an insulation portion connecting the first electrode and the second electrode, a semiconductor layer surrounding the first electrode, the insulation portion, and the second electrode, a gate electrode surrounding a sidewall of the semiconductor layer, a gate insulation layer disposed between the gate electrode and the semiconductor layer, and the first electrode, the insulation portion, and the second electrode are connected to form an integral structure.

In some embodiments, the first electrode, the insulation portion, and the second electrode extend along a direction parallel to the base substrate.

In an exemplary embodiment, the first electrode includes a first sub-portion and a first connection layer surrounding the first sub-portion, the semiconductor layer surrounds the first sub-portion and is in contact with the first sub-portion, the second electrode includes a second sub-portion and a second connection layer surrounding the second sub-portion, the semiconductor layer surrounds the second sub-portion and is in contact with the second sub-portion, on a plane parallel to the base substrate, an orthographic projection of the first connection layer is outside an orthographic projection of the semiconductor layer, and an orthographic projection of the second connection layer is outside the orthographic projection of the semiconductor layer; the insulation portion is in contact with the first sub-portion and the second sub-portion.

In some embodiments, semiconductor layers of transistors of different layers are disconnected.

In some embodiments, the semiconductor layer extends along a direction parallel to the base substrate.

In some embodiments, the 3D stacked semiconductor device further includes: a word line extending along the direction perpendicular to the base substrate; a gate electrode of each of the transistors is part of the word line.

In some embodiments, the 3D stacked semiconductor device further includes a plurality of bit lines distributed in different layers and extending along a direction parallel to the base substrate, and a bit line of the plurality of bit lines and a first electrode of a transistor in a same layer as the bit line are connected to form an integral structure.

In some embodiments, the 3D stacked semiconductor device further includes: a plurality of vias, and a plurality of connection electrodes filling the plurality of vias respectively, wherein a bottom wall of each via exposes one bit line, and a sidewall of the via exposes a bit line through which the via penetrates, and a bit line isolation layer is disposed between a connection electrode of the plurality of connection electrodes and a bit line exposed by a sidewall of a via where the connection electrode is located.

In some embodiments, gate insulation layers of transistors of different layers are connected to be of an integral structure.

In some embodiments, the first electrode includes a first sub-portion and a first connection layer surrounding the first sub-portion, the semiconductor layer surrounds the first sub-portion and the first connection layer and is in contact with the first sub-portion and the first connection layer, the second electrode includes a second sub-portion and a second connection layer surrounding the second sub-portion, the semiconductor layer surrounds the second sub-portion and is in contact with the second sub-portion, on a plane parallel to the base substrate, an orthographic projection of the second connection layer is outside an orthographic projection of the semiconductor layer, and an orthographic projection of the first connection layer is overlapped with the orthographic projection of the semiconductor layer; the insulation portion is in contact with the first sub-portion and the second sub-portion.

In some embodiments, the first sub-portion and the second sub-portion include polysilicon, and the first connection layer and the second connection layer include a metal silicide.

In some embodiments, the 3D stacked semiconductor device further includes: a plurality of word lines distributed in different layers and extending along a direction parallel to the base substrate; a gate electrode of the transistor is a part of a word line in a same layer.

In some embodiments, the 3D stacked semiconductor device further includes: a bit line extending along the direction perpendicular to the base substrate; first electrodes of the plurality of transistors are connected to a same bit line.

An embodiment of the present disclosure provides an electronic device including the 3D stacked semiconductor device as described in any of the above embodiments.

An embodiment of the present disclosure provides a method for manufacturing a 3D stacked semiconductor device, the 3D stacked semiconductor device includes a plurality of transistors stacked along a direction perpendicular to a base substrate and distributed in different layers, and the method for manufacturing the 3D stacked semiconductor device includes:
providing the base substrate, and sequentially and alternately depositing a first insulation thin film and a first conductive thin film on the base substrate and patterning the first insulation thin film and the first conductive thin film to form a stacked structure, wherein the stacked structure includes a stack of first insulation layers and conductive layers which are alternately disposed, and a conductive layer of the conductive layers includes a first conductive portion;
forming a first sacrificial layer, a second sacrificial layer, and a word line region groove, wherein the word line region groove exposes part of a region other than an end portion of each first conductive portion, and the first sacrificial layer and the second sacrificial layer constitute sidewalls of the word line region groove;
performing insulation treatment on a conductive layer located in the word line region groove to form an insulation portion, wherein the first conductive portion is partitioned by the insulation portion to form a first sub-portion and a second sub-portion which are independent; etching the first sacrificial layer and the second sacrificial layer toward a direction away from the insulation portion to expose the conductive layer connected with the insulation portion, an etched thickness of the first sacrificial layer is smaller than a thickness of the first sacrificial layer along an etched direction, and an etched thickness of the second sacrificial layer is smaller than a thickness of the second sacrificial layer along the etched direction;
sequentially depositing a semiconductor thin film, a gate insulation thin film, and a gate electrode thin film on the base substrate to form a semiconductor layer, a gate insulation layer and a gate electrode of a transistor of the plurality of transistors respectively, wherein the semiconductor layer surrounds the first sub-portion, the second sub-portion, and the insulation portion, and the gate electrode surrounds a sidewall of the semiconductor layer; and
performing a resistance reduction treatment on the first sub-portion and the second sub-portion to form a first electrode and a second electrode of the transistor respectively.

In some embodiments, the manufacturing method further includes:
removing the first sacrificial layer and the second sacrificial layer by etching, and removing semiconductor layers covering the first sacrificial layer and the second sacrificial layer by etching to disconnect semiconductor layers of transistors of different layers.

In some embodiments, the performing insulation treatment on the conductive layer located in the word line region groove to form the insulation portion includes: oxidizing the conductive layer located in the word line region groove to form the insulation portion;
the performing the resistance reduction treatment on the first sub-portion and the second sub-portion includes:
exposing at least part of a region of the first sub-portion and at least part of a region of the second sub-portion, and performing a metal silicidation treatment on the exposed region of the first sub-portion and the exposed region of the second sub-portion to form a metal silicide.

In some embodiments, when the gate electrode thin film is deposited, gate electrodes of the plurality of transistors are made be connected to form a word line;
the conductive layer further includes a second conductive portion; the manufacturing method further includes: performing a resistance reduction treatment on the second conductive portion to form a bit line.

In some embodiments, the manufacturing method further includes:
forming a via penetrating through the stacked structure, wherein a sidewall of the via exposes each first sub-portion; and
depositing a conductive thin film filling the via in the via to form a bit line.

Other features and advantages of the present disclosure will be set forth in the following specification, and moreover, partially become apparent from the specification, or are understood by implementing the present disclosure. Objectives and advantages of the present disclosure may be achieved and obtained through structures particularly pointed out in the specification and the drawings.

Other aspects may be understood upon reading and understanding the drawings and detailed description.

### BRIEF DESCRIPTION OF DRAWINGS

Accompanying drawings are used to provide further understanding of technical solutions of the present disclosure, constitute a part of the specification, and are used to explain the technical solutions together with the embodiments of the present disclosure but not to form limitations on the technical solutions of the present disclosure.

FIG. 1A is a schematic diagram of a 3D stacked semiconductor device according to an exemplary embodiment.

FIG. 1B is a schematic cross-sectional view along a direction aa′ in FIG. 1A.

FIG. 2A is a cross-sectional view along a direction perpendicular to a base substrate after a stacked structure is formed according to an exemplary embodiment.

FIG. 2B is a cross-sectional view of the stacked structure shown in FIG. 2A along a horizontal direction of a region where a conductive layer is located.

FIG. 3A is a schematic cross-sectional view along a direction parallel to a base substrate after a stacked structure is patterned according to an exemplary embodiment.

FIG. 3B is a schematic cross-sectional view along a direction bb′ in FIG. 3A.

FIG. 4A is a schematic cross-sectional view along a direction parallel to a base substrate after a stacked structure is filled according to an exemplary embodiment.

FIG. 4B is a schematic cross-sectional view along a direction bb′ in FIG. 4A.

FIG. 5A is a schematic cross-sectional view along a direction parallel to a base substrate after a first sacrificial layer is formed according to an exemplary embodiment.

FIG. 5B is a schematic cross-sectional view along a direction aa′ in FIG. 5A.

FIG. 6A is a schematic cross-sectional view along a direction parallel to a base substrate after a first insulation film of a word line region is removed according to an exemplary embodiment.

FIG. 6B is a schematic cross-sectional view along a direction aa′ in FIG. 6A.

FIG. 7A is a schematic cross-sectional view along a direction parallel to a base substrate after an insulation portion is formed according to an exemplary embodiment.

FIG. 7B is a schematic cross-sectional view along a direction aa′ in FIG. 7A.

FIG. 8A is a schematic cross-sectional view along a direction parallel to a base substrate after a first sacrificial layer and a second sacrificial layer are etched according to an exemplary embodiment.

FIG. 8B is a schematic cross-sectional view along a direction aa′ in FIG. 8A.

FIG. 9 is a schematic cross-sectional view along a direction aa′ after a semiconductor layer, a gate insulation layer, and a gate electrode are formed according to an exemplary embodiment.

FIG. 10A is a schematic cross-sectional view along a direction parallel to a base substrate after an interlayer semiconductor layer is removed according to an exemplary embodiment.

FIG. 10B is a schematic cross-sectional view along a direction aa′ in FIG. 10A.

FIG. 10C is a schematic cross-sectional view along a direction bb′ in FIG. 10A.

FIG. 11A is a schematic cross-sectional view along a direction parallel to a base substrate after a second insulation layer is formed according to an exemplary embodiment.

FIG. 11B is a schematic cross-sectional view along a direction aa′ in FIG. 11A.

FIG. 11C is a schematic cross-sectional view along a direction bb′ in FIG. 11A.

FIG. 12A is a schematic cross-sectional view along a direction parallel to a base substrate after a third sacrificial layer is formed according to an exemplary embodiment.

FIG. 12B is a schematic cross-sectional view along a direction aa′ in FIG. 12A.

FIG. 13A is a schematic cross-sectional view along a direction parallel to a base substrate after a first electrode and a second electrode are formed according to an exemplary embodiment.

FIG. 13B is a schematic cross-sectional view along a direction aa′ in FIG. 13A.

FIG. 14A is a schematic cross-sectional view along a direction parallel to a base substrate after a dielectric layer is formed according to an exemplary embodiment.

FIG. 14B is a schematic cross-sectional view along a direction aa′ in FIG. 14A.

FIG. 15A is a schematic cross-sectional view along a direction parallel to a base substrate after an adhesive layer of different layers are disconnected according to an exemplary embodiment.

FIG. 15B is a schematic cross-sectional view along a direction aa′ in FIG. 15A.

FIG. 16A is a schematic cross-sectional view along a direction parallel to a base substrate after a second plate is formed according to an exemplary embodiment.

FIG. 16B is a schematic cross-sectional view along a direction aa′ in FIG. 16A.

FIG. 17A is a cross-sectional view along a direction cc′ parallel to a base substrate according to an exemplary embodiment.

FIG. 17B is a cross-sectional view along a direction dd′ in FIG. 17A.

FIG. 17C is a cross-sectional view along a direction aa′ in FIG. 17A.

FIG. 17D is a cross-sectional view along a direction ee′ in FIG. 17A.

FIG. 18 is a schematic diagram of a 3D stacked semiconductor device according to another exemplary embodiment.

FIG. 19A is a schematic cross-sectional view along a direction perpendicular to a base substrate 1 after a stacked structure is formed according to an exemplary embodiment.

FIG. 19B is a schematic cross-sectional view along a direction parallel to a base substrate after a stacked structure is formed according to an exemplary embodiment.

FIG. 20A is a schematic cross-sectional view along a direction parallel to a base substrate after a stacked structure is patterned according to an exemplary embodiment.

FIG. 20B is a schematic cross-sectional view along a direction bb′ in FIG. 20A.

FIG. 21A is a schematic cross-sectional view along a direction parallel to a base substrate after a first insulation thin film is filled according to an exemplary embodiment.

FIG. 21B is a schematic cross-sectional view along a direction bb′ in FIG. 21A.

FIG. 22A is a schematic cross-sectional view along a direction parallel to a base substrate after a second sacrificial layer 62 is formed according to an exemplary embodiment.

FIG. 22B is a schematic cross-sectional view along a direction aa′ in FIG. 22A.

FIG. 23A is a schematic cross-sectional view along a direction parallel to a base substrate after a word line region groove C1 is formed according to an exemplary embodiment.

FIG. 23B is a schematic cross-sectional view along a direction aa′ in FIG. 23A.

FIG. 24A is a schematic cross-sectional view along a direction parallel to a base substrate after a first sacrificial layer and a second sacrificial layer are etched according to an exemplary embodiment.

FIG. 24B is a schematic cross-sectional view along a direction aa′ in FIG. 24A.

FIG. 25A is a schematic cross-sectional view along a direction parallel to a base substrate after a semiconductor layer, a gate insulation layer, and a gate electrode are formed according to an exemplary embodiment.

FIG. 25B is a schematic cross-sectional view along a direction aa′ in FIG. 25A.

FIG. 26A is a schematic cross-sectional view along a direction aa′ after a bit line is formed according to an exemplary embodiment.

FIG. 26B is a schematic cross-sectional view along a direction bb′ in FIG. 26A.

FIG. 27 is a schematic cross-sectional view along a direction aa′ after a first plate is formed according to an exemplary embodiment.

FIG. 28 is a schematic cross-sectional view along a direction aa′ after a dielectric layer and a second plate are formed according to an exemplary embodiment.

### DETAILED DESCRIPTION

The embodiments of the present disclosure will be described in detail below in with reference to the accompanying drawings. The embodiments in the present application and features in the embodiments may be combined with each other randomly if there is no conflict.

Unless otherwise defined, technical terms or scientific terms used in the present disclosure shall have general meanings as understood by those of ordinary skills in the art to which the present disclosure pertains.

An implementation of the present disclosure is not necessarily limited to dimensions shown in the drawings, and the shapes and sizes of the components in the drawings do not reflect actual scales. Further, the drawings schematically illustrate ideal examples, but embodiments of the present disclosure are not limited to shapes or values shown in the drawings.

Ordinal numerals such as “first”, “second” and “third” in the present disclosure are provided to avoid confusion between constituent elements, but do not indicate any order, quantity or importance.

In the present disclosure, for convenience, words or expressions indicating orientation or positional relationship such as “middle”, “upper”, “lower”, “front”, “rear”, “vertical”, “horizontal”, “top”, “bottom”, “inner” and “outer” are employed to explain positional relationship of the constituent elements with reference to the accompanying drawings, they are employed for ease of description of the specification and simplification of the description only, but do not indicate or imply that the referred device or element must have a particular orientation and be constructed and operate in a particular orientation, and therefore cannot be construed as limitations on the present disclosure. The positional relationship of the constituent elements is appropriately changed according to a direction in which various constituent elements are described. Therefore, the present disclose is not limited to the words or expressions described in the present disclosure, and replacement may be appropriately made according to the situation.

In the present disclosure, terms “mount”, “couple” and “connect” should be understood broadly, unless otherwise expressly specified and defined. For example, it may be a fixed connection, a detachable connection, or an integral connection; it may be a mechanical connection or an electrical connection; it may be a direct connection, an indirect connection through a middleware, or an internal communication between two elements. For those of ordinary skills in the art, specific meanings of the above terms in the present disclosure may be understood according to actual situations.

In the present disclosure, a transistor refers to an element including at least three terminals, i.e., a gate electrode, a drain electrode, and a source electrode. A transistor has a channel region between a drain electrode (drain electrode terminal, drain region, or drain) and a source electrode (source electrode terminal, source region, or source), and a current can flow through the drain electrode, the channel region, and the source electrode. In the present disclosure, the channel region refers to a region through which the current mainly flows.

In the present disclosure, the first electrode may be a drain electrode and the second electrode may be a source electrode, or the first electrode may be a source electrode and the second electrode may be a drain electrode. In cases that transistors with opposite polarities are used, or a current direction changes during operation of a circuit, or the like, functions of the “source electrode” and the “drain electrode” may sometimes be exchanged. Therefore, in the present disclosure, the “source electrode” and the “drain electrode” are interchangeable.

In the present disclosure, “electrical connection” includes the case where the constituent elements are connected together by elements having certain electrical effects. There is no special restriction on “elements with certain electrical effects” as long as they can transmit and receive electrical signals between connected constituent elements. Examples of “elements having certain electrical effects” include not only electrodes and wirings, but also switching elements (such as transistors), resistors, inductors, capacitors, and other elements having various functions, etc.

In the present disclosure, “parallel” refers to approximately parallel or almost parallel, for example, a state in which the angle formed by two straight lines is −10 degrees or more and 10 degrees or less, and therefore further includes a state in which the angle is −5 degrees or more and 5 degrees or less. In addition, “perpendicular” refers to “approximately perpendicular”, for example, a state in which the angle formed by two straight lines is 80 degrees or more and 100 degrees or less, and therefore further includes a state in which the angle is 85 degrees or more and 95 degrees or less.

In the present disclosure, “A and B are disposed in a same layer” means that A and B are simultaneously formed through a same patterning process. “An orthographic projection of B is within a range of an orthographic projection of A” means that a boundary of the orthographic projection of B falling within a range of a boundary of the orthographic projection of A, or a boundary of the orthographic projection of A is overlapped with a boundary of the orthographic projection of B.

“A and B are of an integrated structure” in embodiments of the present disclosure may mean that there is no obvious boundary interface, such as obvious faultage or gaps, viewed from the microstructure. Generally, connected film layers formed by patterning on one film layer are an integrated structure. For example, A and B form one film layer using a same material and simultaneously form a structure with a connection relationship through the same patterning process.

An embodiment of the present disclosure provides a 3D stacked semiconductor device, including:
a plurality of transistors distributed in different layers and stacked along a direction perpendicular to a base substrate; and
a transistor includes a first electrode, a second electrode, an insulation portion connecting the first electrode and the second electrode, a semiconductor layer surrounding the first electrode, the insulation portion, and the second electrode, a gate electrode surrounding a sidewall of the semiconductor layer, a gate insulation layer disposed between the gate electrode and the semiconductor layer, and the first electrode, the insulation portion, and the second electrode are connected to form an integral structure.

In the 3D stacked semiconductor device provided in the present embodiment, the first electrode, the insulation portion, and the second electrode are of an integral structure, a process is simple, stacking is convenient, and an integration level may be improved.

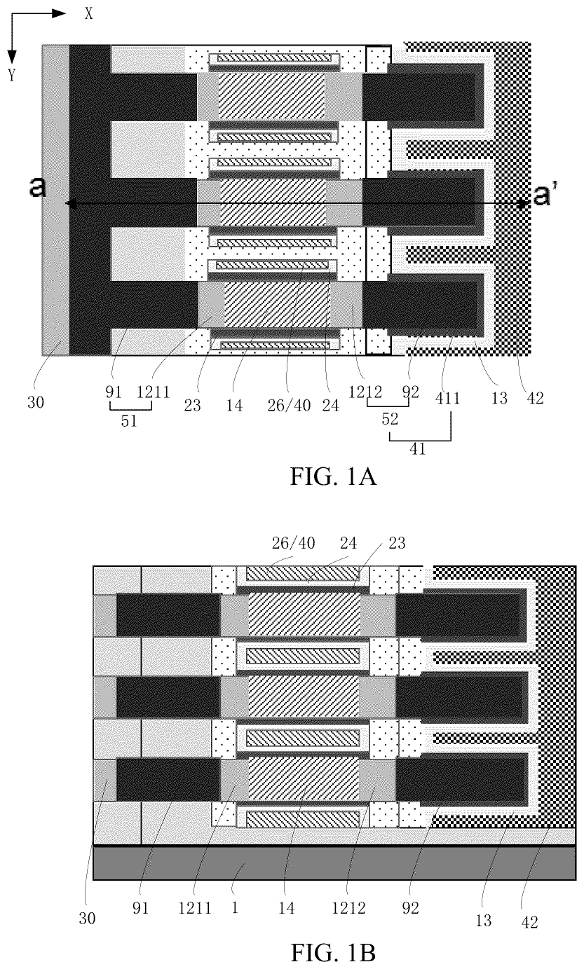

FIG. 1A is a cross-sectional view of a 3D stacked semiconductor device along a direction parallel to a base substrate according to an exemplary embodiment; FIG. 1B is a cross-sectional view along a direction aa′ in FIG. 1A. As shown in FIGS. 1A and 1B, the present embodiment provides a 3D stacked semiconductor device, which may include:
a plurality of transistors, distributed in different layers and stacked along a direction perpendicular to a base substrate 1;
a transistor may include a first electrode 51, a second electrode 52, an insulation portion 14 connecting the first electrode 51 and the second electrode 52, a semiconductor layer 23 surrounding the first electrode 51, the insulation portion 14, and the second electrode 52, a gate electrode 26 surrounding a sidewall of the semiconductor layer 23, a gate insulation layer 24 disposed between the gate electrode 26 and the semiconductor layer 23, and the first electrode 51, the insulation portion 14, and the second electrode 52 are connected to form an integral structure.

The sidewall of the semiconductor layer 23 may be a surface of the semiconductor layer 23 on a side away from the first electrode 51, the insulation portion 14, and the second electrode 52.

In an exemplary embodiment, the first electrode 51, the insulation portion 14, and the second electrode 52 may extend along a direction parallel to the base substrate 1.

In an exemplary embodiment, the first electrode 51 may include a first sub-portion 1211 and a first connection layer 91 surrounding the first sub-portion 1211, the semiconductor layer 23 surrounds the first sub-portion 1211 and is in contact with the first sub-portion 1211, the second electrode 52 may include a second sub-portion 1212 and a second connection layer 92 surrounding the second sub-portion 1212, the semiconductor layer 23 surrounds the second sub-portion 1212 and is in contact with the second sub-portion 1212, on a plane parallel to the base substrate 1, an orthographic projection of the first connection layer 91 may be outside an orthographic projection of the semiconductor layer 23, and an orthographic projection of the second connection layer 92 may be outside the orthographic projection of the semiconductor layer 23; the insulation portion 14 is in contact with the first sub-portion 1211 and the second sub-portion 1212. The first electrode 51, the insulation portion 14, and the second electrode 52 are connected to form an integral structure, and the first sub-portion 1211, the insulation portion 14, and the second sub-portion 1212 are connected to form an integral structure. At the time of preparation, a first conductive portion may be formed, and part of a region other than an end portion of the first conductive portion may be insulated into the insulation portion 14, and on the first conductive portion, one located respectively at both ends of the insulation portion 14 is the first sub-portion 1211, and the other is the second sub-portion 1212. In this embodiment, when the first connection layer 91 surrounds the first sub-portion 1211, only a part of the first sub-portion 1211 is covered and another part of the first sub-portion 1211 is exposed, that is, a region of the first sub-portion 1211 close to the insulation portion 14 is exposed; when the second connection layer 92 surrounds the second sub-portion 1212, only a part of the second sub-portion 1212 is covered and another part of the second sub-portion 1212 is exposed, that is, a region of the second sub-portion 1212 close to the insulation portion 14 is exposed.

In an exemplary embodiment, a resistance of the first connection layer 91 is smaller than a resistance of the first sub-portion 1211, and a resistance of the second connection layer 92 is smaller than a resistance of the second sub-portion 1212, so that a contact resistance may be reduced.

In an exemplary embodiment, the first sub-portion 1211 may include a first sidewall and a second sidewall, the semiconductor layer 23 surrounds the first sidewall and is in contact with the first sidewall, on a plane parallel to the base substrate 1, and an orthographic projection of the second sidewall is outside an orthographic projection of the semiconductor layer 23, the second sub-portion 1212 may include a third sidewall and a fourth sidewall, and the semiconductor layer 23 surrounds the third sidewall and is in contact with the third sidewall, on the plane parallel to the base substrate 1, an orthographic projection of the fourth sidewall is outside the orthographic projection of the semiconductor layer 23. That is, the semiconductor layer 23 surrounds only a part of sidewalls of the first sub-portion 1211, and surrounds only a part of sidewalls of the second sub-portion 1212.

In an exemplary embodiment, on the plane parallel to the base substrate 1, an orthographic projection of the insulation portion 14 may be located within the orthographic projection of the semiconductor layer 23. In the present embodiment, the semiconductor layer 23 may completely cover the insulation portion 14.

In an exemplary embodiment, the semiconductor layer 23 surrounding the first sidewall may be the semiconductor layer 23 fully surrounding the first sidewall, that is, the semiconductor layer 23 surrounding the first sidewall may have a closed ring shape along a cross section perpendicular to the base substrate 1. The semiconductor layer 23 surrounding the third sidewall may be the semiconductor layer 23 fully surrounding the third sidewall, that is, the semiconductor layer 23 surrounding the third sidewall may have a closed ring shape along a cross section perpendicular to the base substrate 1. In some embodiments, the surrounding may be partial surrounding, and a cross section after surrounding is not closed, but presents a ring shape. For example, an annular shape having an opening.

In an exemplary embodiment, semiconductor layers 23 of transistors of different layers may be disconnected. A solution provided by the present embodiment may eliminate a parasitic transistor.

In an exemplary embodiment, the semiconductor layer 23 may extend along a direction parallel to the base substrate 1.

In an exemplary embodiment, the 3D stacked semiconductor device may further include: a word line 40 extending along a direction perpendicular to the base substrate 1; the gate electrode 26 of each transistor is part of the word line 40.

In an exemplary embodiment, the word line 40 extending along the direction perpendicular to the base substrate 1 may extend along a straight line direction. In some embodiments, an orthographic projection of the gate electrode 26 of each transistor on a plane perpendicular to the base substrate 1 may be at a same position, and then gate electrodes 26 of each transistor of different layers are connected to form a linear word line 40.

In an exemplary embodiment, the 3D stacked semiconductor device may further include a plurality of bit lines 30 distributed in different layers and extending along a direction parallel to the base substrate 1, and a bit line 30 may be connected with a first electrode 51 of a transistor in a same layer as the bit line 30 to form an integral structure.

In an exemplary embodiment, the bit line 30 may extend along a second direction Y, the first electrode 51 may extend along a first direction X, and the first direction X may be perpendicular to the second direction Y, but it is not limited to this, the first direction X may intersect with the second direction Y.

In an exemplary embodiment, orthographic projections of semiconductor layers 23 or gate insulation layers 24 or gate electrodes 26 of transistors of different layers may be overlapped on a plane parallel to the base substrate 1. The orthographic projections of the semiconductor layers 23, the gate insulation layers 24, or the gate electrodes 26 are overlapped, which may make the 3D stacked semiconductor device compact, reduce an area occupied by the semiconductor device, and improve a density of the semiconductor device.

In an exemplary embodiment, on a plane parallel to the base substrate 1, orthographic projections of first electrodes 51 or second electrodes 52 of the transistors of different layers may be overlapped. In a solution according to the embodiment, in a process, a first electrode and a second electrode stacked in multiple layers may be formed through relative stacking of a conductive layer and an insulation layer and then through a mask, thus implementation of the process is simple. In addition, a structure of a 3D memory may be made more compact.

In an exemplary embodiment, gate insulation layers 24 of transistors of different layers may be connected to be of an integral structure. According to a solution provided by this embodiment, gate insulation layers of a plurality of transistors in a same layer may be formed through one preparation process, and a process is simple and convenient.

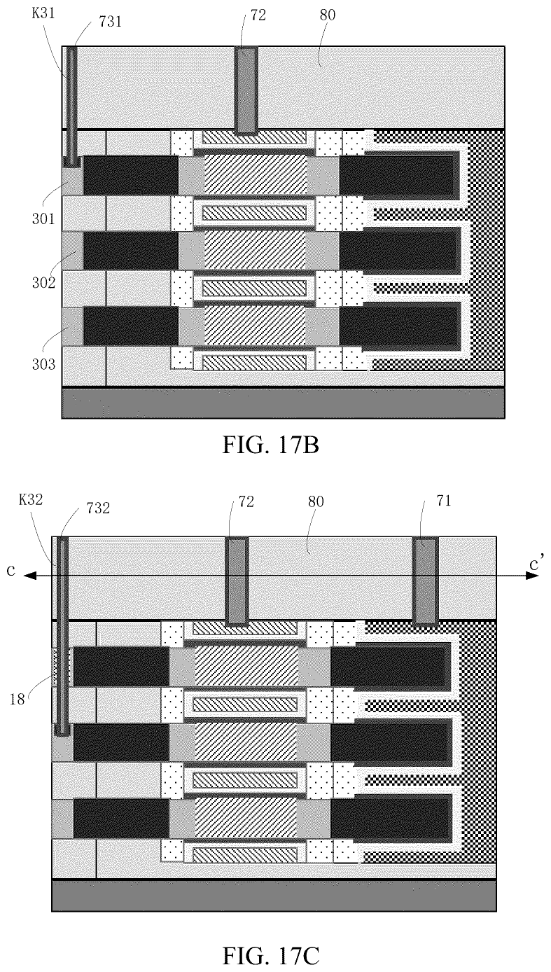

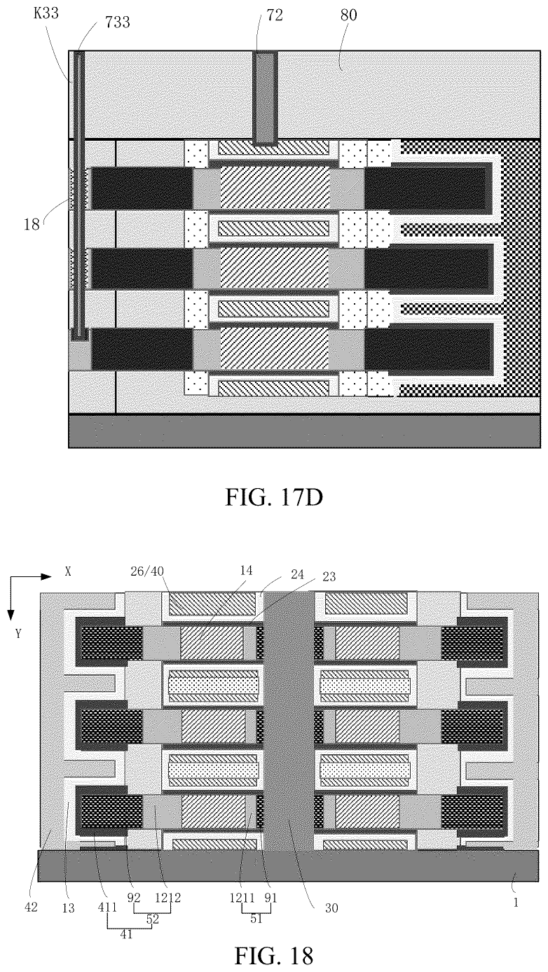

In an exemplary embodiment, the 3D stacked semiconductor device may further include a plurality of third vias K3, and a plurality of third connection electrodes 73 respectively filling the plurality of third vias K3, wherein a bottom wall of each third via K3 exposes one bit line 30 respectively, and a sidewall of the third via K3 exposes a bit line 30 penetrating through the third via K3, and a bit line isolation layer 18 is disposed between the third connection electrode 73 and the bit line 30 exposed by the sidewall of the third via K3 where the third connection electrode 73 is located. The bit line isolation layer 18 achieves isolation between the third connection electrode 73 and the penetrating bit line 30. As shown in FIGS. 17A to 17D, FIG. 17A is a cross-sectional view along a direction cc′ parallel to the base substrate 1, FIG. 17B is a cross-sectional view along a direction dd′ in FIG. 17A, FIG. 17C is a cross-sectional view along a direction aa′ in FIG. 17A, and FIG. 17D is a cross-sectional view along a direction ee′ in FIG. 17A. FIGS. 17A to 17D show three third vias K31, K32, K33, and third connection electrodes (referred to as a fourth connection electrode 731, a fifth connection electrode 732, and a sixth connection electrode 733 respectively) located in the three third vias K31, K32, K33 respectively, and a first bit line 301, a second bit line 302, and a third bit line 303. As may be seen, a bit line isolation layer 18 is disposed between the fifth connection electrode 732 and the first bit line 301, so that the fifth connection electrode 732 is isolated from the first bit line 301, and a bit line isolation layer 18 is disposed between the sixth connection electrode 733 and, the first bit line 301 and the second bit line 302, so that the sixth connection electrode 733 is isolated from the first bit line 301 and the second bit line 302. According to a solution provided in this embodiment, a bit line isolation layer is used for isolation, and compared with an implementation solution in which a bit line is led out in a stepped manner, a device area may be reduced as much as possible.

In an exemplary embodiment, the 3D stacked semiconductor device may further include a capacitor, and the capacitor may include a first plate 41 and a second plate 42, and the first plate 41 is connected with the second electrode 52.

In an exemplary embodiment, the first plate 41 and the second electrode 52 may have an integral structure.

In an exemplary embodiment, the first plate 41 may include a second electrode 52 and an adhesive layer 411, and the adhesive layer 411 covers an end surface of the second electrode 52 away from the first electrode 51 and a sidewall adjacent to the end surface. The adhesive layer 411 may enhance adhesiveness of the second electrode 52 to another film layer.

In an exemplary embodiment, the adhesive layer 411 is, for example, Titanium Nitride (TiN).

In an exemplary embodiment, second plates 42 of capacitors of transistors of different layers may be connected to be of an integral structure.

In an exemplary embodiment, the capacitor may further include a dielectric layer 13 disposed between the first plate 41 and the second plate 42.

In an exemplary embodiment, dielectric layers 13 of the capacitors of the transistors of different layers may be connected to be of an integral structure. The capacitors of different layers share a same dielectric layer.

In an exemplary embodiment, a plurality of 3D stacked semiconductor devices may form a 3D stacked semiconductor device array, for example, three 3D stacked semiconductor devices form a 3D stacked semiconductor device array, and the three 3D stacked semiconductor devices may be distributed along a direction parallel to the base substrate 1, for example, along a second direction Y. First electrodes 51 of transistors in a same layer may be connected to a same bit line 30.

There are various fabrication methods for the 3D stacked semiconductor device, and the embodiment of the present application exemplarily introduces an implementation solution from the viewpoint of understanding a structure of the case, which is used for understanding the above structure, but is not used for limiting the above structure.

Technical solutions of the embodiment will be further explained through a preparation process of the 3D stacked semiconductor device of the embodiment. A “patterning process” mentioned in the embodiments includes film layer deposition, photoresist coating, mask exposure, development, etching, photoresist stripping, and other treatments, and is a mature preparation process in related technologies. A “photolithography process” in the embodiments includes film layer coating, mask exposure, and development, and is a mature preparation process in related technologies. Known processes such as sputtering, evaporation, chemical vapor deposition may be used for the deposition, known coating processes may be used for the coating, and known approaches may be used for etching, which are not specifically limited here. In description of the embodiments, it should be understood that a “thin film” refers to a layer of thin film made of a certain material on a substrate using a deposition or coating process. If the “thin film” does not need a patterning process or photolithography process during the whole manufacturing process, the “thin film” may also be called a “layer”. If the “thin film” needs a patterning process or photolithography process during the whole manufacturing process, it is called a “thin film” before the patterning process and a “layer” after the patterning process. The “layer” after the patterning process or photolithography process contains at least one “pattern”.

In an exemplary embodiment, a manufacturing process of a 3D stacked semiconductor device may include following acts.

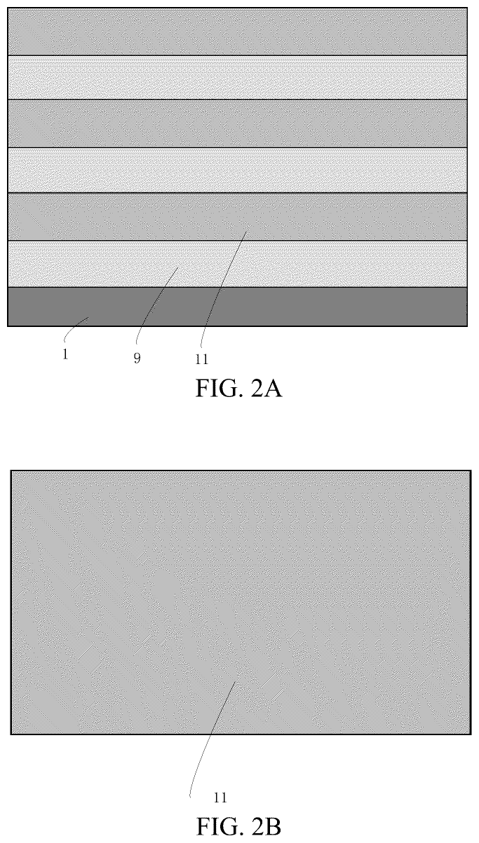

101) A first insulation thin film 9 and a first conductive thin film 11 are sequentially and alternately deposited on a base substrate 1 to form a stacked structure, as shown in FIGS. 2A and 2B, wherein FIG. 2A is a schematic cross-sectional view along a direction perpendicular to the base substrate 1 after the stacked structure is formed, and FIG. 2B is a schematic cross-sectional view along a direction parallel to the base substrate 1 in FIG. 2A (a cross-sectional view of the first conductive thin film 11).

In an exemplary embodiment, the first insulation thin film 9 may be a low-K dielectric layer, i.e., a dielectric layer having a dielectric constant K<3.9, which includes, but is not limited to, a silicon oxide such as Silicon dioxide (SiO2).

In an exemplary embodiment, the first conductive thin film 11 may include, but is not limited to, polysilicon.

The stacked structure shown in FIG. 2A includes three layers of first insulation thin films 9 and three layers of first conductive thin films 11, by way of example only, and in another embodiment, the stacked structure may include more or fewer layers of first insulation thin films 9 and first conductive thin films 11 alternately disposed.

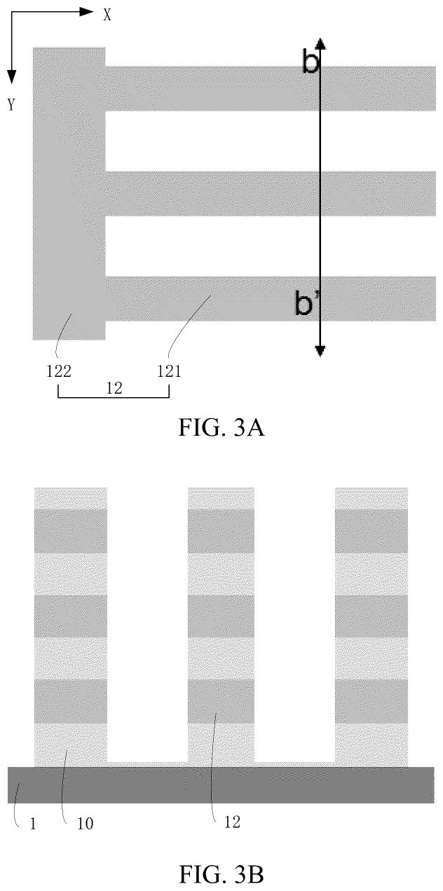

102) The stacked structure is patterned to form a stacked structure including alternately stacked conductive layers 12 and first insulation layers 10. As shown in FIGS. 3A and 3B, wherein FIG. 3A is a schematic cross-sectional view along a direction parallel to the base substrate 1 after the stacked structure is patterned (a cross section of a conductive layer 12), and FIG. 3B is a schematic cross-sectional view along a direction bb′ in FIG. 3A, and the direction bb′ may be perpendicular to the base substrate 1.

The patterning the stacked structure to form the stacked structure including the conductive layers 12 and the first insulation layers 10 may include:
etching the stacked structure using a dry etching method, removing the first conductive thin film 11 and the first insulation thin film 9 of a preset isolation region, and forming the stacked structure including the conductive layers 12 and the first insulation layers 10. A conductive layer 12 may include a preset electrode pattern, and as shown in FIG. 3A, the preset electrode pattern may include a first conductive portion 121 and a second conductive portion 122, wherein the first conductive portion 121 may extend along a first direction X, the second conductive portion 122 may extend along a second direction Y, and the first direction X and the second direction Y may be perpendicular. Among them, the preset electrode pattern shown in FIG. 3A is merely an example, and the preset electrode pattern may have other shapes. In an exemplary embodiment, the direction bb′ may be parallel to the second direction Y.

In an exemplary embodiment, the first conductive portion 121 may be a strip-shaped electrode, and the second conductive portion 122 may be a strip-shaped electrode. The preset electrode pattern may include a plurality of first conductive portions 121 and one second conductive portion 122, and the plurality of first conductive portions 121 may be parallel to each other and connected to different positions of the second conductive portion 122.

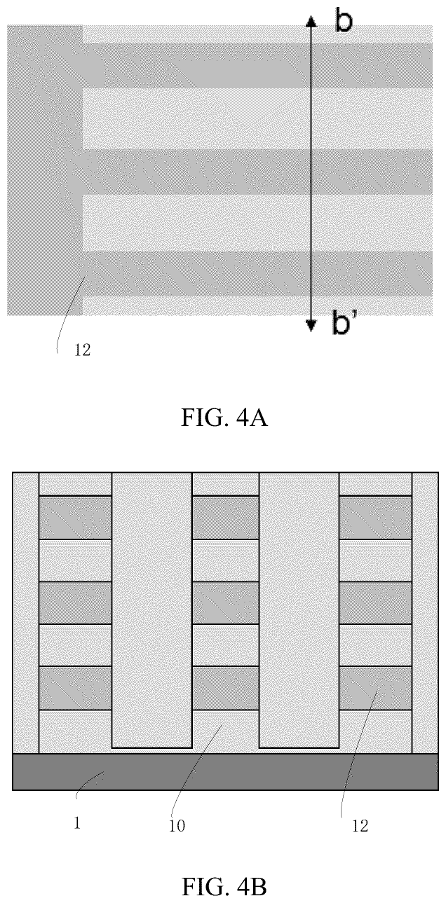

When the stacked structure is etched, all of first conductive thin films 11 of the stacked structure are penetrated. 103) The preset isolation region is filled with a first insulation thin film, as shown in FIGS. 4A and 4B, wherein FIG. 4A is a schematic cross-sectional view along a direction parallel to the base substrate 1 after the stacked structure is filled, and FIG. 4B is a schematic cross-sectional view along the direction bb′ in FIG. 4A.

In an exemplary embodiment, the first insulation thin film may be deposited using a Chemical Vapor Deposition (CVD) method.

104) A first sacrificial layer 61 and a second sacrificial layer 62 are formed.

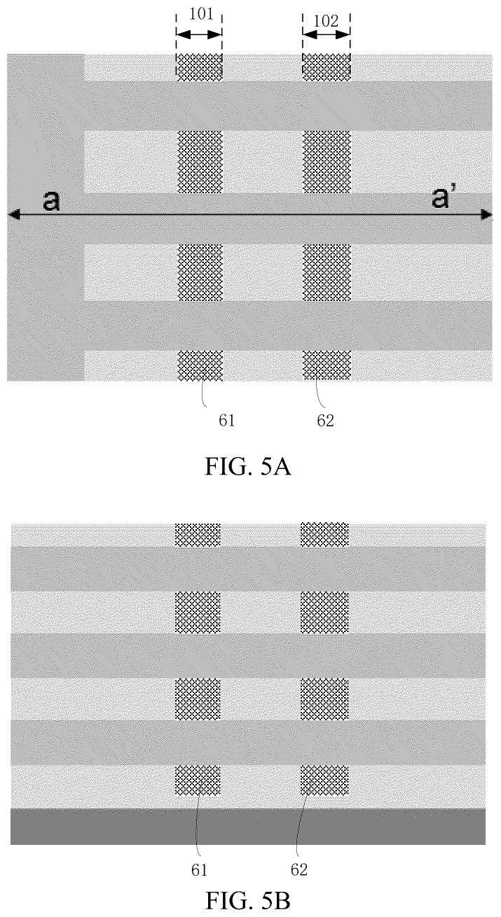

The forming the first sacrificial layer 61 and the second sacrificial layer 62 may include: removing the first insulation thin film of a first frame region 101, depositing a sacrificial layer thin film in the first frame region 101, forming the first sacrificial layer 61, removing the first insulation thin film in a second frame region 102, depositing a sacrificial layer thin film in the second frame region 102, forming the second sacrificial layer 62, wherein the first sacrificial layer 61 and the second sacrificial layer 62 are disposed opposite to each other, as shown in FIGS. 5A and 5B. Among them, FIG. 5A is a schematic cross-sectional view along a direction parallel to the base substrate 1 after the first sacrificial layer 61 and the second sacrificial layer 62 are formed, and FIG. 5B is a schematic cross-sectional view along a direction aa′ in FIG. 5A. The direction aa′ is perpendicular to the base substrate 1, and the direction aa′ may be perpendicular to the direction bb'.

In an exemplary embodiment, the removing the first insulation thin film in the first frame region 101 and the second frame region 102 may include: completely removing the first insulation thin film in the first frame region 101 and the second frame region 102 from top to bottom of the stacked structure by dry etching, or partially removing a part of the first insulation thin film covering the base substrate 1 to avoid exposure of the base substrate 1; and laterally removing the first insulation thin film between conductive layers 12 in the first frame region 101 and the second frame region 102 by wet etching.

In an exemplary embodiment, the sacrificial layer thin film includes, but is not limited to, silicon nitride (SiN).

A word line region 200 is between the first sacrificial layer 61 and the second sacrificial layer 62, and a word line is subsequently formed in the word line region 200.

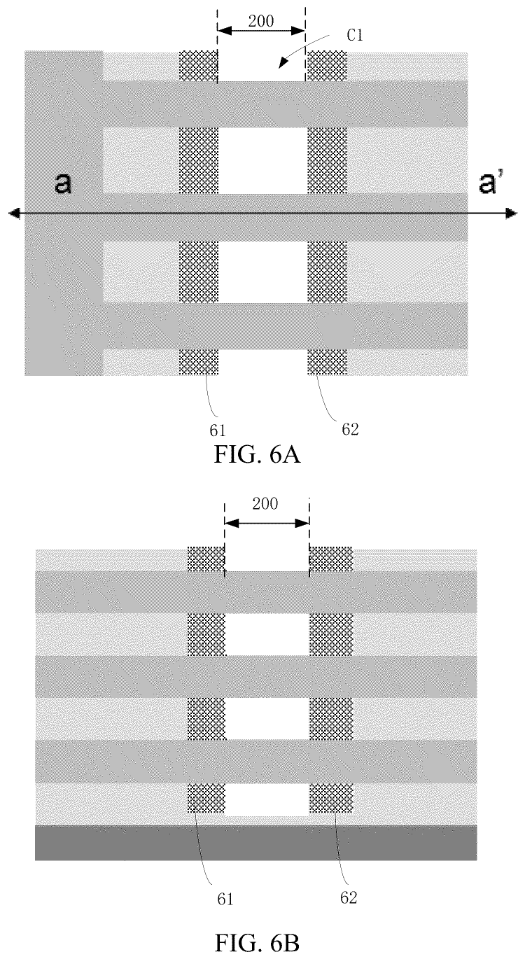

105) The first insulation thin film of the word line region 200 is removed to form a word line region groove C1, as shown in FIGS. 6A and 6B, wherein FIG. 6A is a schematic cross-sectional view along a direction parallel to the base substrate 1 after the first insulation thin film of the word line region 200 is removed, and FIG. 6B is a schematic cross-sectional view along a direction aa′ in FIG. 6A. The word line region groove C1 exposes a conductive layer 12 located in the word line region 200. At this time, the first sacrificial layer 61 and the second sacrificial layer 62 serve as sidewalls of the word line region groove C1 respectively, and a bottom wall of the word line region groove C1 may be the first insulation thin film, that is, the word line region groove C1 does not expose the base substrate 1. The word line region groove C1 exposes part of a region other than an end portion of each conductive layer 12.

In an exemplary embodiment, the removing the first insulation thin film of the word line region 200 may include: removing the first insulation thin film of the word line region 200 from top to bottom of the stacked structure by dry etching, and laterally removing the first insulation thin film located between conductive layers 12 in the word line region 200 by wet etching. When the first insulation thin film is etched, the first insulation thin film having a preset thickness at the bottom may be retained without exposing the base substrate 1.

106) An insulation portion 14 is formed.

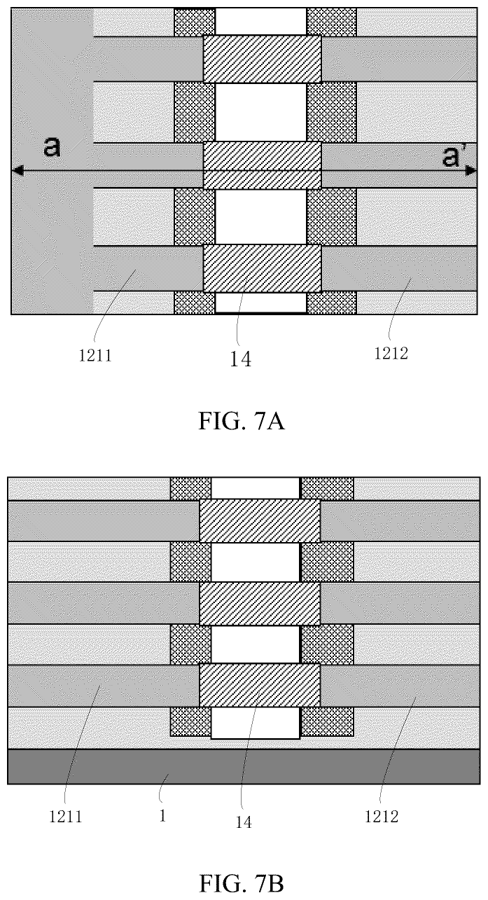

The forming the insulation portion 14 may include: performing an insulation treatment on the conductive layer 12 exposed in the word line region groove C1 (for example, oxidizing into an insulation material) to form the insulation portion 14, as shown in FIGS. 7A and 7B, wherein FIG. 7A is a schematic cross-sectional view along a direction parallel to the base substrate 1 after the insulation portion 14 is formed, and FIG. 7B is a schematic cross-sectional view along a direction aa′ in FIG. 7A. The insulation portion 14 may divide the first conductive portion 121 into a first sub-portion 1211 and a second sub-portion 1212 independent of each other, the first sub-portion 1211 may subsequently form a first electrode 51 of a transistor, the second sub-portion 1212 may subsequently form a second electrode 52 of the transistor, and the first sub-portion 1211 is connected with a second conductive portion 122.

In an exemplary embodiment, the conductive layer 12 may be polysilicon, and the polysilicon is oxidized to form SiO2, that is, the insulation portion 14 may be SiO2.

107) The first sacrificial layer 61 and the second sacrificial layer 62 are etched.

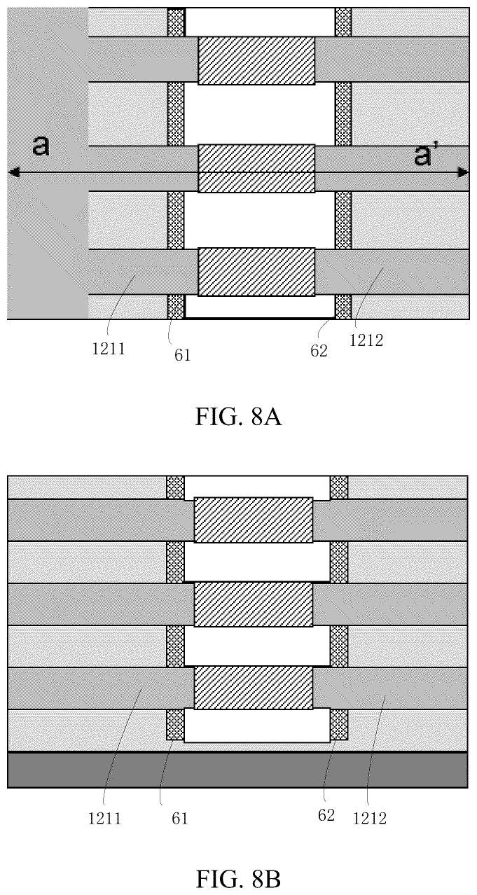

The etching the first sacrificial layer 61 and the second sacrificial layer 62 may include: etching the first sacrificial layer 61 and the second sacrificial layer 62 toward a direction away from the insulation portion 14 to expose a conductive layer 12 connected with the insulation portion 14, wherein an etched thickness of the first sacrificial layer 61 is smaller than a thickness of the first sacrificial layer 61 along an etched direction, and an etched thickness of the second sacrificial layer 62 is smaller than a thickness of the second sacrificial layer 62 along the etched direction; that is, the first sacrificial layer 61 and the second sacrificial layer 62 are not completely etched away, and part of the first sacrificial layer 61 and part of the second sacrificial layer 62 are retained, as shown in FIGS. 8A and 8B, wherein FIG. 8A is a schematic cross-sectional view along a direction parallel to the base substrate after the first sacrificial layer and the second sacrificial layer are etched, and FIG. 8B is a schematic cross-sectional view along a direction aa′ in FIG. 8A.

In an exemplary embodiment, wet etching may be used, and etching may be performed by selecting a solution with a relatively large selective ratio of the insulation portion 14 and the first sacrificial layer 61. For example, when a material of the insulation portion 14 is SiO2 and a material of the first sacrificial layer 61 is SiN, an acid solution (such as phosphoric acid) having a relatively large selective ratio of SiO2 and SiN is used to etch laterally a SiN thin film between layers toward both sides away from the insulation portion 14.

108) A semiconductor layer 23, a gate insulation layer 24, and a gate electrode 26 are formed.

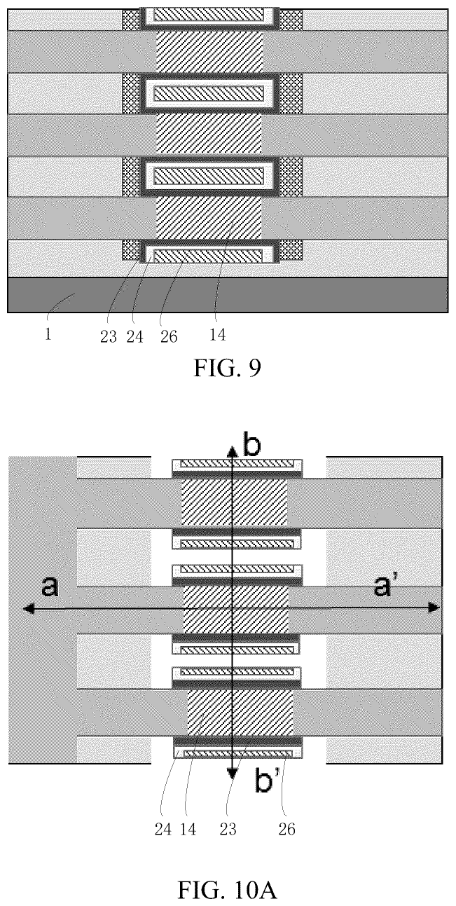

The forming the semiconductor layer 23, the gate insulation layer 24, and the gate electrode 26 may include: sequentially depositing a semiconductor thin film, a gate insulation thin film, and a gate electrode thin film on the base substrate 1 on which the aforementioned structure is formed to form the semiconductor layer 23, the gate insulation layer 24, and the gate electrode 26 respectively, as shown in FIG. 9. FIG. 9 is a schematic cross-sectional view along a direction aa′ after the semiconductor layer 23, the gate insulation layer 24, and the gate electrode 26 are formed. The semiconductor layer 23 covers the insulation portion 14, an exposed region of the first sub-portion 1211, an exposed region of the second sub-portion 1212, and a sidewall of the first sacrificial layer 61 facing the word line region 200. Gate electrodes 26 of transistors of different layers in a same column are connected to form a word line 40.

A distance between first conductive portions 121 of a same conductive layer 12 and a distance between different conductive layers 12 may be controlled, so that gate electrodes 26 of transistors of different layers in a same column are connected with each other to form the word line 40 when the gate electrode thin film is deposited; and, there is a gap between gate electrodes 26 of transistors in a same layer.

In an exemplary embodiment, the semiconductor thin film includes, but is not limited to, Indium Gallium Zinc Oxide (IGZO), Indium Tin Oxide (ITO), Indium Zinc Oxide (IZO), and the like. When IGZO is used as a semiconductor layer, it has advantages of low leakage and short refresh time.

In an exemplary embodiment, the gate insulation thin film may be a High-K material, including but not limited to Aluminum Oxide (Al2O3), Hafnium dioxide (HfO2), and the like.

In an exemplary embodiment, the gate electrode thin film includes, but is not limited to, titanium nitride/tungsten (a stacked structure composed of TiN/W) or a transparent conductive oxide thin film, and the transparent conductive oxide thin film includes, but is not limited to, ITO, Aluminum-doped Zinc Oxide (AZO), IZO, and the like.

In an exemplary embodiment, the semiconductor thin film, the gate insulation thin film, and the gate electrode thin film may be deposited through an Atomic Layer Deposition (ALD) manner.

109) The semiconductor layer 23 between layers is removed.

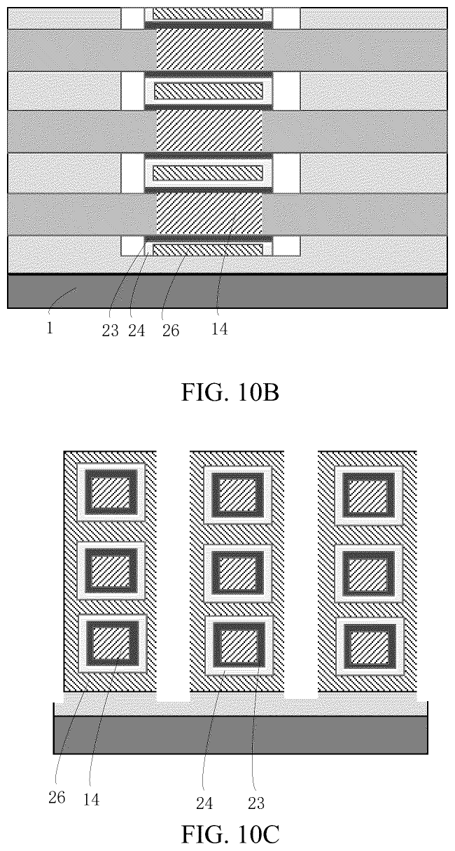

The removing the semiconductor layer 23 between layers may include: removing the first sacrificial layer 61 and the second sacrificial layer 62 by etching, removing the semiconductor layer 23 covering the first sacrificial layer 61 and the second sacrificial layer 62 by etching so that semiconductor layers 23 of transistors of different layers are disconnected from each other, thereby eliminating a parasitic transistor, at this time, the semiconductor layer 23 only covers the insulation portion 14, an exposed region of the first sub-portion 1211, and an exposed region of the second sub-portion 1212, as shown in FIGS. 10A, 10B, and 10C. Among them, FIG. 10A is a schematic cross-sectional view along a direction parallel to the base substrate 1 after the semiconductor layer 23 between layers is removed (a cross section of a region where a conductive layer 12 is located), FIG. 10B is a schematic cross-sectional view along a direction aa′ in FIG. 10A, and FIG. 10C is a schematic cross-sectional view along a direction bb′ in FIG. 10A.

110) A second insulation layer 15 is formed.

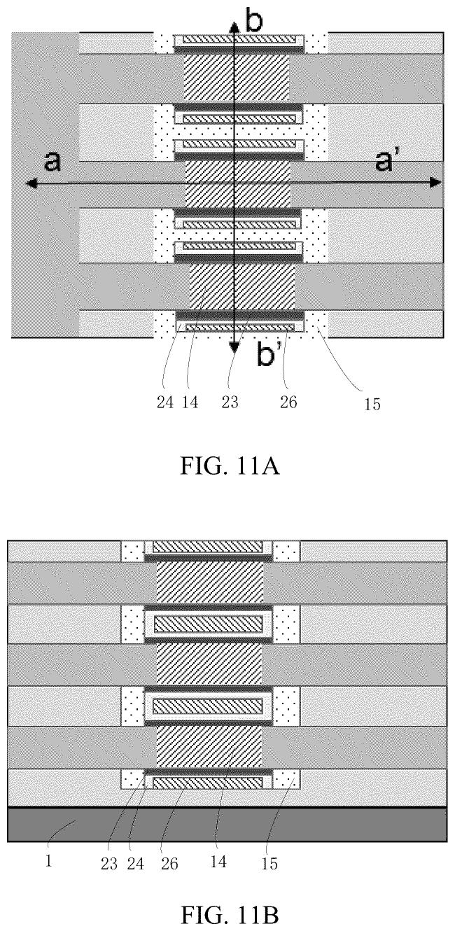

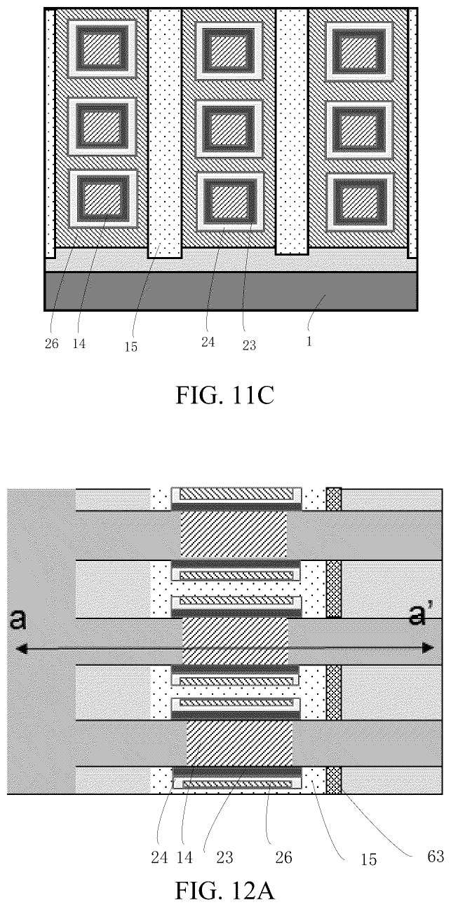

The forming the second insulation layer 15 may include: depositing a second insulation thin film on the base substrate 1 on which the aforementioned structure is formed to form the second insulation layer 15, as shown in FIGS. 11A, 11B, and 11C, wherein FIG. 11A is a schematic cross-sectional view along a direction parallel to the base substrate 1 after the second insulation layer 15 is formed, FIG. 11B is a schematic cross-sectional view along a direction aa′ in FIG. 11A, and FIG. 11C is a schematic cross-sectional view along a direction bb′ in FIG. 11A. The second insulation layer 15 is distributed in a region where the first sacrificial layer 61 and the second sacrificial layer 62 that are etched away are located, and in a region where the etched semiconductor layer 23 between layers is located.

In an exemplary implementation, the second insulation thin film is, for example, a low-K dielectric material, i.e., a dielectric material having a dielectric constant K<3.9, including but not limited to silicon oxide, such as Silicon dioxide (SiO2).

111) A third sacrificial layer 63 is formed.

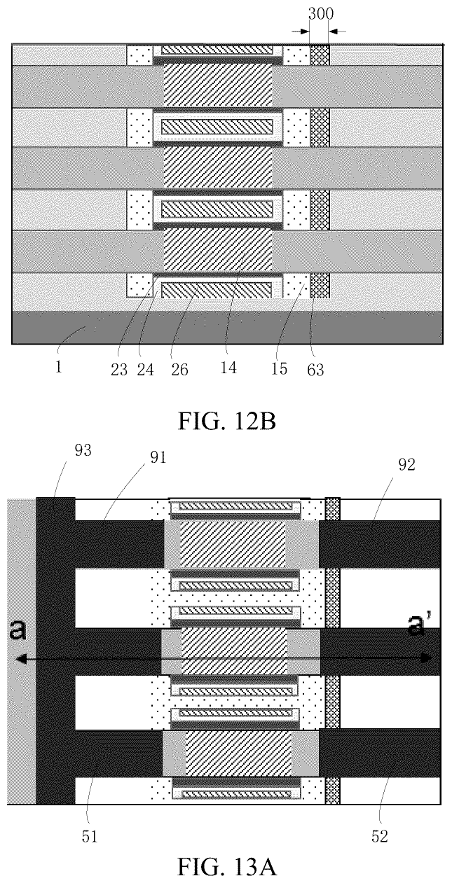

The forming the third sacrificial layer 63 may include: removing the second insulation thin film of a third frame region 300, depositing a sacrificial layer thin film on the third frame region 300, and forming the third sacrificial layer 63, as shown in FIGS. 12A and 12B, wherein FIG. 12A is a schematic cross-sectional view along a direction parallel to the base substrate 1 after the third sacrificial layer 63 is formed, and FIG. 12B is a schematic cross-sectional view along a direction aa′ in FIG. 12A.

The third frame region 300 is disposed on a side of the word line region 200 away from the second conductive portion 122.

112) A first electrode 51 and a second electrode 52 are formed.

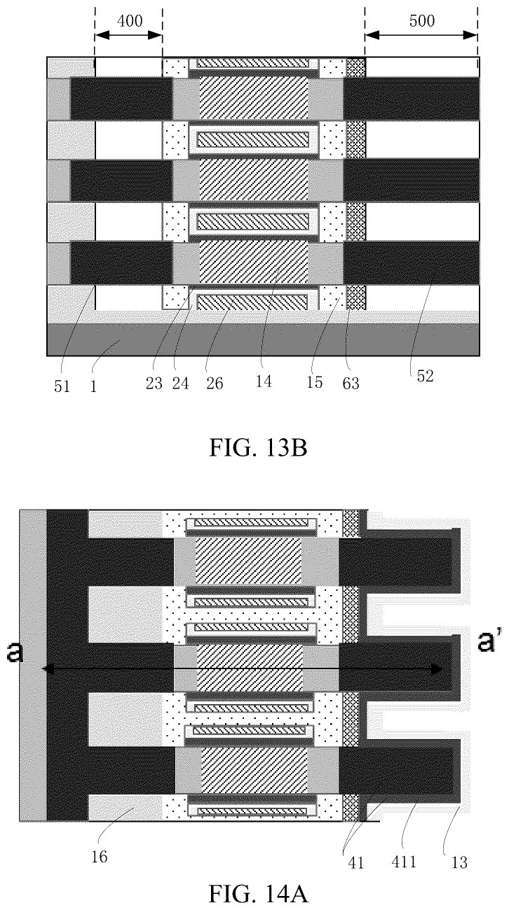

The forming the first electrode 51 and the second electrode 52 may include:
removing the first insulation thin film of a first region 400 and a second region 500, exposing part of a region of the first sub-portion 1211, and exposing part of a region of the second sub-portion 1212, and exposing a sidewall of the second conductive portion 122 facing the word line region 200; and
depositing a metal on surfaces of exposed regions of the first sub-portion 1211, the second sub-portion 1212, and the second conductive portion 122, wherein the metal reacts with the surfaces of the first sub-portion 1211, the second sub-portion 1212, and the second conductive portion 122 respectively, to form a metal silicide to generate a first connection layer 91, a second connection layer 92, and a third connection layer 93 respectively. The first connection layer 91, the second connection layer 92, and the third connection layer 93 may reduce a resistance. The first connection layer 91 and the first sub-portion 1211 serve as the first electrode 51, the second connection layer 92 and the second sub-portion 1212 serve as the second electrode 52, and the third connection layer 92 and the second conductive portion 122 serve as a bit line 30, as shown in FIGS. 13A and 13B, wherein FIG. 13A is a schematic cross-sectional view along a direction parallel to the base substrate 1 after the first electrode 51 and the second electrode 52 are formed, and FIG. 13B is a schematic cross-sectional view along a direction aa′ in FIG. 13A. The first connection layer 91 may surround the first sub-portion 1211, and the surrounding may be a full surrounding, that is, a cross section of the first connection layer 91 in a direction perpendicular to the base substrate 1 may have a closed ring shape. Similarly, a cross section of the second connection layer 92 in the direction perpendicular to the base substrate 1 may have a closed ring shape, which will not be described again.

In an exemplary embodiment, the deposited metal may be deposited Titanium (Ti), Cobalt (Co), Nickel Platinum (NiPt), or the like, and the metal silicide may be Titanium disilicide (TiSi2), Cobalt disilicide (CoSi2), Nickel Platinum Silicide (NiPtSi), or the like.

113) A first plate 41 and a dielectric layer 13 are formed.

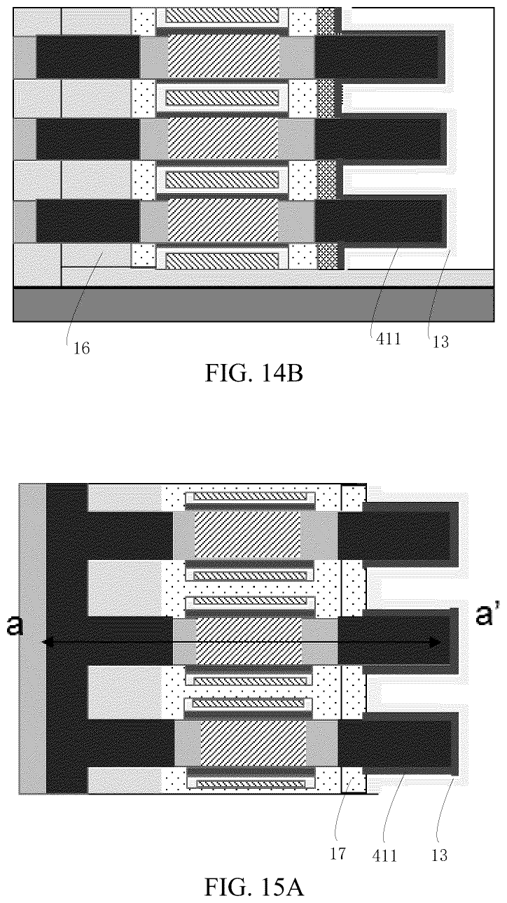

The forming the first plate 41 and the dielectric layer 13 may include:
depositing a third insulation thin film on the first region 400 to form a third insulation layer 16;
depositing a titanium nitride thin film on the base substrate 1 on which the aforementioned structure is formed, forming an adhesive layer 411 covering a sidewall of the third sacrificial layer 63 away from the word line region 200 and covering a surface of the second electrode 52 located in the second region 500, wherein the adhesive layer 411 and the second electrode 52 constitutes a first plate 41 of a capacitor;
depositing a dielectric thin film on the base substrate 1 on which the aforementioned structure is formed to form a dielectric layer 13, wherein the dielectric layer 13 covers a surface of the first plate 41 away from the word line region 200, as shown in FIGS. 14A and 14B, wherein FIG. 14A is a schematic cross-sectional view along a direction parallel to the base substrate 1 after the dielectric layer 13 is formed, and FIG. 14B is a schematic cross-sectional view along a direction aa′ in FIG. 14A.

In an exemplary embodiment, the adhesive layer 411 may be formed using a material other than a titanium nitride thin film.

114) The adhesive layer 411 of different transistors is disconnected.

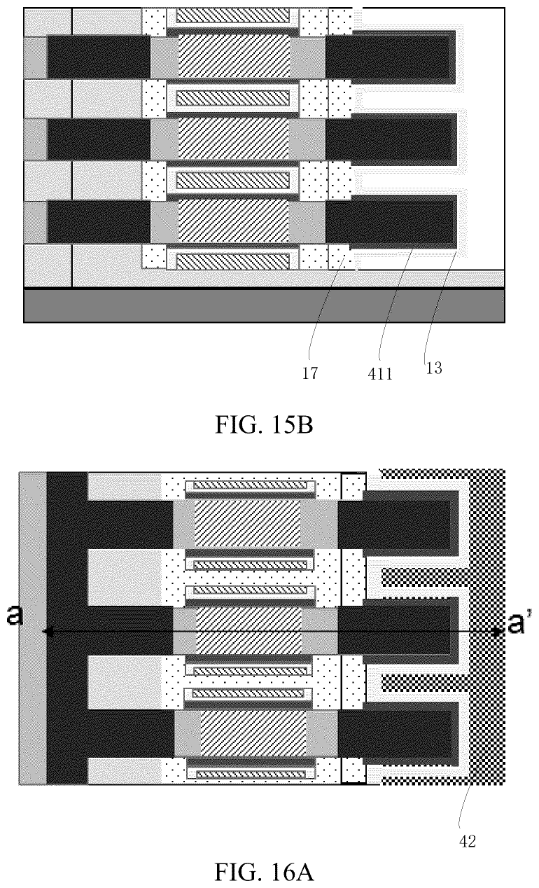

The disconnecting the adhesive layer 411 of different transistors may include:
removing the third sacrificial layer 63 by etching; and removing the adhesive layer 411 covering a sidewall of the third sacrificial layer 63 by etching, so that the adhesive layer 411 covering different second electrodes 52 is disconnected, and first plates 41 of different devices are avoided from being connected;
depositing a fourth insulation thin film on the base substrate 1 on which the aforementioned structure is formed to form a fourth insulation layer 17, wherein the fourth insulation layer 17 fills a region where the third sacrificial layer 63 is located and a region where a portion of the adhesive layer 411 is etched is located, as shown in FIGS. 15A and 15B, wherein FIG. 15A is a schematic cross-sectional view along a direction parallel to the base substrate after the adhesive layer of different layers is disconnected, and FIG. 15B is a schematic cross-sectional view along a direction aa′ in FIG. 15A.

In an exemplary embodiment, the adhesive layer 411 may not be provided, and the third sacrificial layer 63 may not be formed.

In an exemplary embodiment, the fourth insulation thin film may be a low-K dielectric material, that is, a dielectric material having a dielectric constant K<3.9, including but not limited to silicon oxide such as Silicon dioxide (SiO2).

115) A second plate 42 is formed.

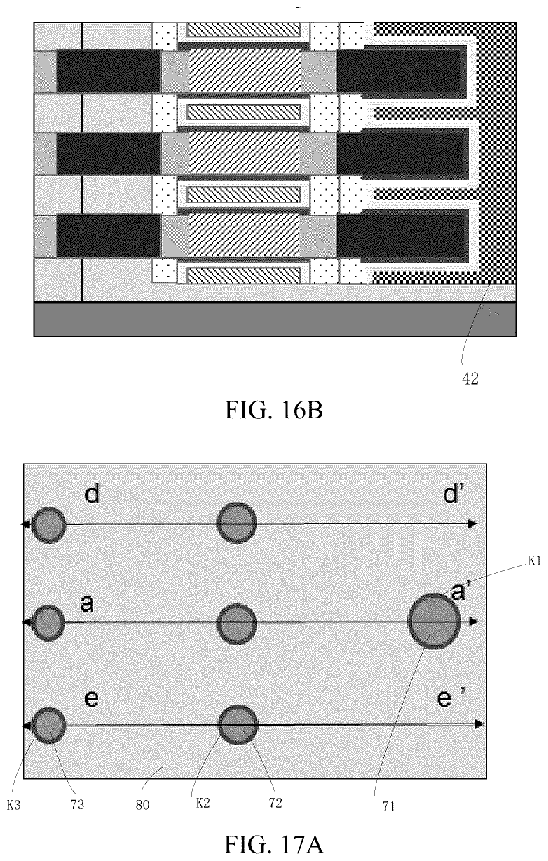

The forming the second plate 42 may include: depositing a conductor material on the substrate 1 on which the aforementioned structure is formed to form a second plate 42, wherein the second plate 42 covers a sidewall surface of the dielectric layer 13 away from the word line region 200, as shown in FIGS. 16A and 16B, wherein FIG. 16A is a schematic cross-sectional view along a direction parallel to the base substrate 1 after the second plate 42 is formed, and FIG. 16B is a schematic cross-sectional view along a direction aa′ in FIG. 16A.

In an exemplary embodiment, the conductor material may include, but is not limited to, polysilicon, TiN, W, and the like.

116) A connection electrode is formed.

The forming the connection electrode may include:
depositing an interlayer dielectric material on the base substrate 1 on which the aforementioned structure is formed to form an isolation layer 80;
forming a first via K1 and a plurality of second vias K2, wherein the first via K1 exposes the second plate 42, each of the second vias K2 exposes one word line 40; depositing a second conductive thin film in the first via K1 to form a first connection electrode 71, and depositing a second conductive thin film in the plurality of second vias K2 respectively to form a plurality of second connection electrodes 72;
forming a plurality of third vias K3, wherein bottom portions of the plurality of third vias K3 expose a plurality of bit lines 30 respectively; etching a region of the third vias K3 where penetrated bit lines 30 are located toward a direction far away from the third vias K3, depositing a fifth insulation thin film in the etched region to form a bit line isolation layer 18, and depositing a second conductive thin film in the plurality of third vias K3 to form a plurality of third connection electrodes 73 respectively, wherein each of the third connection electrodes 73 is connected with one bit line 30 and the third connection electrodes 73 are isolated from bit lines 30 of other layers through the bit line isolation layer 18, as shown in FIGS. 17A to 17D, wherein FIG. 17A is a cross-sectional view along a direction cc′ parallel to the base substrate 1, FIG. 17B is a cross-sectional view along a direction dd′ in FIG. 17A, FIG. 17C is a cross-sectional view along a direction aa′ in FIG. 17A, and FIG. 17D is a cross-sectional view along a direction ee′ in FIG. 17A; or, oxidizing a surface of a bit line 30 exposed by a sidewall of a third via K3 (that is, a surface, exposed within the third via K3, of a bit line 30 which is penetrated by the third via K3) to form a bit line isolation layer 18, thereby achieving isolation of the third connection electrodes 73 from bit lines 30 of other layers (the bit line 30 exposed by the sidewall of the third via K3).

Take three third vias K31, K32, and K33 and three-layer bit lines as an example. Among them, for distinction, a bit line farthest from the base substrate 1 is referred to as a first bit line 301, a bit line 30 closest to the base substrate 1 is referred to as a third bit line 303, and a second bit line 302 is between the first bit line 301 and the third bit line 303.

A bottom wall of the via K31 exposes the first bit line 301, and a second conductive thin film is deposited on the via K31 to form a fourth connection electrode 731 connected with the first bit line 301, as shown in FIG. 17B.

A bottom wall of the via K32 exposes the second bit line 302, and the via K32 penetrates the first bit line 301, a region of the via K32 located in the first bit line 301 is etched toward a direction away from the via K32, a fifth insulation thin film is deposited in the etched region to form a bit line isolation layer 18, and a second conductive thin film filling the via K32 is deposited in the via K32 to form a fifth connection electrode 732 connected with the second bit line 302, as shown in FIG. 17C.

A bottom wall of the via K33 exposes the third bit line 303, and the via K33 penetrates the first bit line 301 and the second bit line 302, a region of the via K33 located in the first bit line 301 is etched toward a direction away from the via K33, a region of the via K33 located in the second bit line 302 is etched toward a direction away from the via K33, a fifth insulation thin film is deposited in etched regions to form a bit line isolation layer 18, a second conductive thin film filling the via K33 is deposited on the via K33 to form a sixth connection electrode 733 connected with the third bit line 303, as shown in FIG. 17D.

In an exemplary embodiment, the interlayer dielectric material includes, but is not limited to, SiO2, Boro-Phospho-Silicate Glass (BPSG), a low-K dielectric material, and the like.

In an exemplary embodiment, the second conductive thin film may have a multilayer structure including Ti/TiN/W or the like. The deposition of the second conductive thin film may be sequential deposition of Ti, TiN, W, or the like.

In an exemplary embodiment, cross-sections of the vias K1, K2, and K3 may be square, circular, or other shapes along a direction parallel to the base substrate 1.

FIG. 18 is a schematic cross-sectional view of a 3D stacked semiconductor device according to another exemplary embodiment along a direction perpendicular to a base substrate. As shown in FIG. 18, the 3D stacked semiconductor device provided by the present embodiment may include:
a plurality of transistors, distributed in different layers and stacked along a direction perpendicular to a base substrate 1;
a transistor may include a first electrode 51, a second electrode 52, an insulation portion 14 connecting the first electrode 51 and the second electrode 52, a semiconductor layer 23 surrounding the first electrode 51, the insulation portion 14, and the second electrode 52, a gate electrode 26 surrounding a sidewall of the semiconductor layer 23, a gate insulation layer 24 disposed between the gate electrode 26 and the semiconductor layer 23, and the first electrode 51, the insulation portion 14, and the second electrode 52 are connected to form an integral structure.

In an exemplary embodiment, the first electrode 51, the insulation portion 14, and the second electrode 52 may extend along a direction parallel to the base substrate 1.

In an exemplary embodiment, the first electrode 51 may include a first sub-portion 1211 and a first connection layer 91 surrounding the first sub-portion 1211, the semiconductor layer 23 surrounds the first sub-portion 1211 and the first connection layer 91, and is in contact with the first sub-portion 1211 and the first connection layer 91, and the second electrode 52 includes a second sub-portion 1212 and a second connection layer 92 surrounding the second sub-portion 1212, the semiconductor layer 23 surrounds the second sub-portion 1212 and is in contact with the second sub-portion 1212, on a plane parallel to the base substrate 1, an orthographic projection of the second connection layer 92 is outside an orthographic projection of the semiconductor layer 23, and an orthographic projection of the first connection layer 91 is overlapped with the orthographic projection of the semiconductor layer 23. The insulation portion 14 is in contact with the first sub-portion 1211 and the second sub-portion 1212.

The first electrode 51, the insulation portion 14, and the second electrode 52 are connected to form an integral structure, and the first sub-portion 1211, the insulation portion 14, and the second sub-portion 1212 are connected to form an integral structure. At the time of preparation, a first conductive portion may be formed, and part of a region other than an end portion of the first conductive portion may be insulated into the insulation portion 14, and on the first conductive portion, one located respectively at both ends of the insulation portion 14 is the first sub-portion 1211, and the other is the second sub-portion 1212.

A resistance of the first connection layer 91 is smaller than a resistance of the first sub-portion 1211, and a resistance of the second connection layer 92 is smaller than a resistance of the second sub-portion 1212, so that a contact resistance may be reduced.

In an exemplary embodiment, the first sub-portion 1211 and the second sub-portion 1212 include polysilicon, and the first connection layer 91 and the second connection layer 92 include a metal silicide.

In an exemplary embodiment, on a plane parallel to the base substrate 1, an orthographic projection of the first sub-portion 1211 may be located within an orthographic projection of the semiconductor layer 23, the second sub-portion 1212 may include a third sidewall and a fourth sidewall, the semiconductor layer 23 surrounds the third sidewall and is in contact with the third sidewall, on the plane parallel to the base substrate 1, an orthographic projection of the fourth sidewall is outside the orthographic projection of the semiconductor layer 23. That is, the semiconductor layer 23 may surround all of sidewalls of the first sub-portion 1211 and surround only part of sidewalls of the second sub-portion 1212.

In an exemplary embodiment, on the plane parallel to the base substrate 1, an orthographic projection of the insulation portion 14 may be located within the orthographic projection of the semiconductor layer 23.

In an exemplary embodiment, the semiconductor layer 23 surrounding the first sub-portion 1211 may be the semiconductor layer 23 fully surrounding the first sub-portion 1211, that is, the semiconductor layer 23 surrounding the first sub-portion 1211 may have a closed ring shape along a cross section perpendicular to the base substrate 1. The semiconductor layer 23 surrounding the third sidewall may be the semiconductor layer 23 fully surrounding the third sidewall, that is, the semiconductor layer 23 surrounding the third sidewall may have a closed ring shape along a cross section perpendicular to the base substrate. In some embodiments, the surrounding may be partial surrounding, and a cross section after surrounding is not closed, but presents a ring shape, for example, an annular shape having an opening.

In an exemplary embodiment, semiconductor layers 23 of transistors of different layers may be disconnected. A solution provided by the present embodiment may eliminate a parasitic transistor.

In an exemplary embodiment, the semiconductor layer 23 may extend along a direction parallel to the base substrate 1.

In an exemplary embodiment, the 3D stacked semiconductor device may further include: a bit line 30 extending along a direction perpendicular to the base substrate 1; first electrodes 51 of the plurality of transistors may be connected to a same bit line 30.

In an exemplary embodiment, the bit line 30 extending along the direction perpendicular to the base substrate 1 may extend along a straight line direction.

In an exemplary embodiment, the 3D stacked semiconductor device may further include a plurality of word lines 40 distributed in different layers and extending along a direction parallel to the base substrate 1, and a gate electrode 26 of a transistor is a part of a word line 40 in a same layer.

In an exemplary embodiment, the word line 40 may extend along a second direction Y, the first electrode 51 may extend along a first direction X, and the first direction X may be perpendicular to the second direction Y.

In an exemplary embodiment, orthographic projections of semiconductor layers 23 or gate insulation layers 24 or gate electrodes 26 of transistors of different layers may be overlapped on a plane parallel to the base substrate 1. The orthographic projections of the semiconductor layers 23 or the gate insulation layers 24 or the gate electrodes 26 may make the 3D stacked semiconductor device compact.

In an exemplary embodiment, on a plane parallel to the base substrate 1, orthographic projections of first electrodes 51 or second electrodes 52 of the transistors of different layers may be overlapped. In a solution according to the embodiment, in a process, a first electrode and a second electrode stacked in multiple layers may be formed through relative stacking of a conductive layer and an insulation layer and then through a mask, thus implementation of the process is simple. In addition, a structure of a 3D memory may be made more compact.

In an exemplary embodiment, gate insulation layers 24 of transistors of different layers may be connected to be of an integral structure. According to a solution provided by this embodiment, gate insulation layers of a plurality of transistors in a same layer may be formed through one preparation process, and a process is simple and convenient.

In an exemplary embodiment, the 3D stacked semiconductor device may further include a capacitor, and the capacitor may include a first plate 41 and a second plate 42, and the first plate 41 is connected with the second electrode 52.

In an exemplary embodiment, the first plate 41 and the second electrode 52 may have an integral structure.

In an exemplary embodiment, the first plate 41 may include a second electrode 52 and an adhesive layer 411, and the adhesive layer 411 covers an end surface of the second electrode 52 away from the first electrode 51 and a side wall adjacent to the end surface. The adhesive layer 411 may enhance adhesiveness of the second electrode 52 to another film layer.

In an exemplary embodiment, the adhesive layer 411 is, for example, TiN.

In an exemplary embodiment, second plates 42 of capacitors of transistors of different layers may be connected to be of an integral structure.

In an exemplary embodiment, the capacitor may further include a dielectric layer 13 disposed between the first plate 41 and the second plate 42.

In an exemplary embodiment, dielectric layers 13 of the capacitors of the transistors of different layers may be connected to be of an integral structure. The capacitors of different layers share a same dielectric layer.

In an exemplary embodiment, a plurality of 3D stacked semiconductor devices may form a 3D stacked semiconductor device array, for example, three 3D stacked semiconductor devices form a 3D stacked semiconductor device array, and the three 3D stacked semiconductor devices may be distributed along a direction parallel to the base substrate 1, for example, along the second direction Y. Gate electrodes of transistors in a same layer may be connected to form a word line 40.

In the above-described embodiment, a transistor and a capacitor constitute a memory device of 1T1C, but the embodiment of the present disclosure is not limited thereto, and a transistor may constitute a memory device with another data storage element, for example, a transistor and a transistor constitute a memory device of 2T0C, and the like.

In an exemplary embodiment, a manufacturing process of a 3D stacked semiconductor device may include following acts.

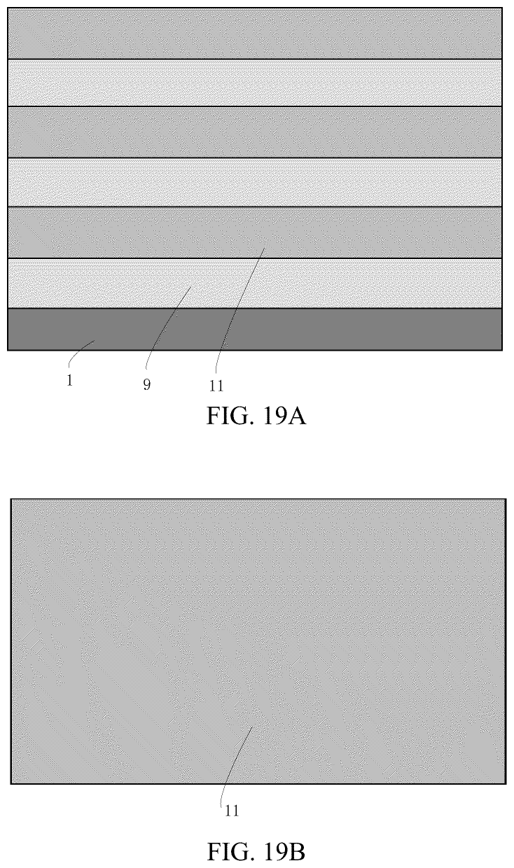

201) A first insulation thin film 9 and a first conductive thin film 11 are sequentially and alternately deposited on a base substrate 1 to form a stacked structure, as shown in FIGS. 19A and 19B, wherein FIG. 19A is a schematic cross-sectional view along a direction perpendicular to the base substrate 1, and FIG. 19B is a schematic cross-sectional view along a direction parallel to the base substrate 1 (and is a cross section of a region where the first conductive thin film 11 is located).

In an exemplary embodiment, the first insulation thin film 9 may be a low-K dielectric layer, i.e., a dielectric layer having a dielectric constant K<3.9, which includes, but is not limited to, a silicon oxide such as Silicon dioxide (SiO2).

In an exemplary embodiment, the first conductive thin film 11 may include, but is not limited to, polysilicon.

The stacked structure shown in FIG. 19A includes three layers of first insulation thin films 9 and three layers of first conductive thin films 11, by way of example only, and in another embodiment, the stacked structure may include more or fewer layers of first insulation thin films 9 and first conductive thin films 11 alternately disposed.

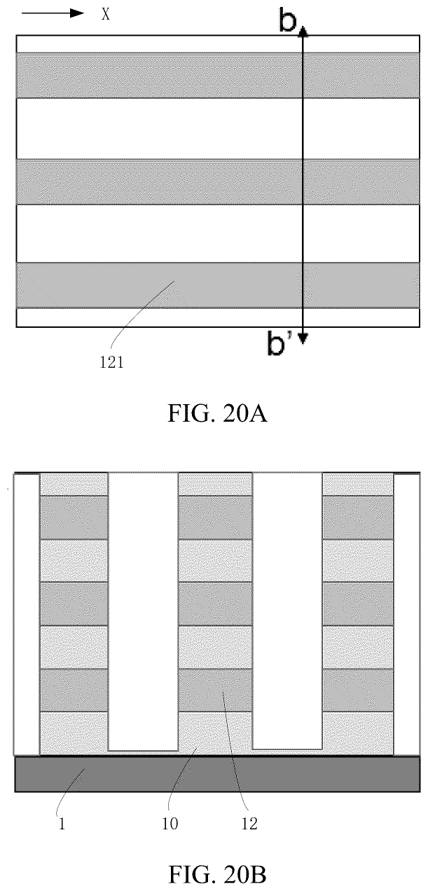

202) The stacked structure is patterned to form a stacked structure including alternately stacked conductive layers 12 and first insulation layers 10. As shown in FIGS. 20A and 20B, wherein FIG. 20A is a schematic cross-sectional view along a direction parallel to the base substrate 1 after the stacked structure is patterned, and FIG. 20B is a schematic cross-sectional view along a direction bb′ in FIG. 20A, and the direction bb′ may be perpendicular to the base substrate 1.

The patterning the stacked structure to form the stacked structure including the conductive layers 12 and the first insulation layers 10 may include:
etching the stacked structure by using a dry etching method, removing a first conductive thin film 11 and a first insulation thin film 9 of a preset isolation region, and forming a stacked structure including a conductive layer 12 and a first insulation layer 10; the conductive layer 12 may include a preset electrode pattern, and as shown in FIG. 20A, the preset electrode pattern may include a plurality of strip-shaped electrodes extending along a first direction X, that is, a first conductive portion 121, wherein the preset electrode pattern shown in FIG. 20A is merely an example, and the preset electrode pattern may have another shape. In an exemplary embodiment, the direction bb′ may be perpendicular to the first direction X.

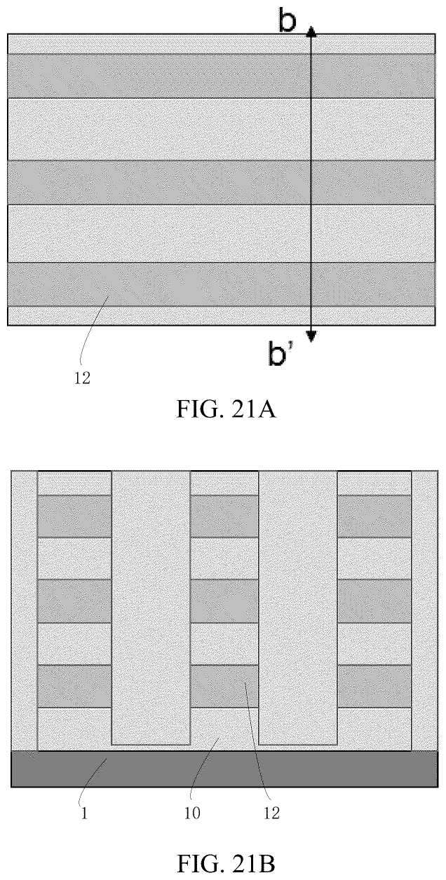

203) The preset isolation region is filled with a first insulation thin film, as shown in FIGS. 21A and 21B, wherein FIG. 21A is a schematic cross-sectional view along a direction parallel to the base substrate 1 after the first insulation thin film is filled, and FIG. 21B is a schematic cross-sectional view along the direction bb′ in FIG. 21A.

In an exemplary embodiment, the first insulation thin film may be deposited using a Chemical Vapor Deposition (CVD) method.

204) A first sacrificial layer 61 and a second sacrificial layer 62 are formed.

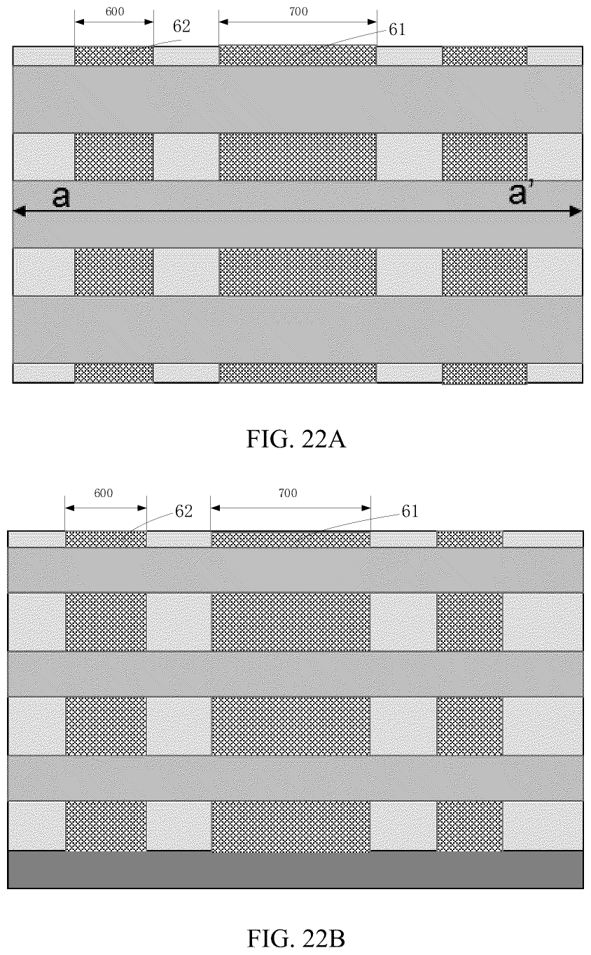

The forming the first sacrificial layer 61 and the second sacrificial layer 62 may include removing the first insulation thin film of a fourth frame region 600, depositing a sacrificial layer thin film in the fourth frame region 600, forming the second sacrificial layer 62, and removing the first insulation thin film of a bit line region 700, depositing the sacrificial layer thin film in the bit line region 700, forming the first sacrificial layer 61, as shown in FIGS. 22A and 22B. Among them, FIG. 22A is a schematic cross-sectional view along a direction parallel to the base substrate 1 after the first sacrificial layer 61 and the second sacrificial layer 62 are formed, and FIG. 22B is a schematic cross-sectional view along a direction aa′ in FIG. 22A. The direction aa′ may be perpendicular to the base substrate 1, and the direction aa′ may be perpendicular to the direction bb′.

In an exemplary embodiment, removing the first insulation thin film of the fourth frame region 600 or the bit line region 700 may include: completely removing the first insulation thin film of the fourth frame region 600 or the bit line region 700 from top to bottom of the stacked structure by dry etching, or partially removing the first insulation thin film covering the base substrate 1 to avoid exposure of the base substrate 1; and laterally removing the first insulation thin film between conductive layers 12 in the fourth frame region 600 or the bit line region 700 by wet etching.

In an exemplary embodiment, the sacrificial layer thin film includes, but is not limited to, SiN.

205) A word line region groove C1 and an insulation portion 14 are formed.

The forming the word line region groove C1 may include: removing the first insulation thin film located between the second sacrificial layer 62 and the first sacrificial layer 61, and forming the word line region groove C1 having the second sacrificial layer 62 and the first sacrificial layer 61 as sidewalls respectively, wherein the word line region groove C1 exposes a conductive layer 12 located between the second sacrificial layer 62 and the first sacrificial layer 61.

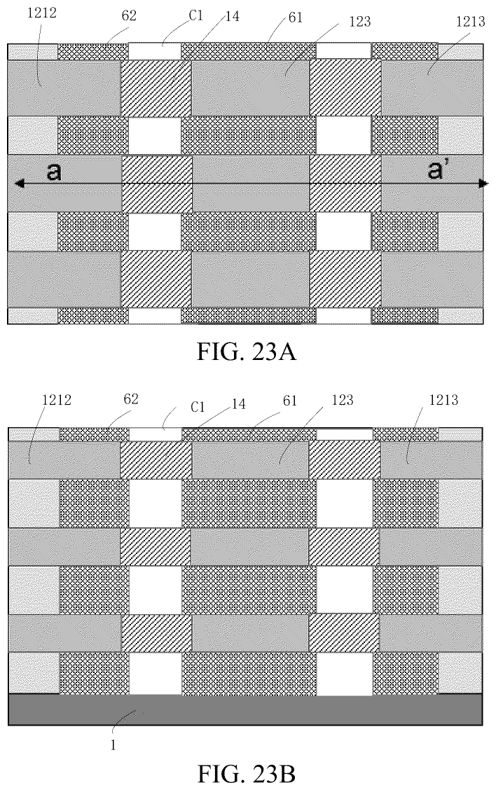

The conductive layer 12 exposed in the word line region groove C1 is insulated (for example, oxidized into an insulation material) to form an insulation portion 14, the insulation portion 14 divides the first conductive portion 121 into an intermediate portion 123 and a second sub-portion 1212 which are independent of each other, one end of the insulation portion 14 is connected with the intermediate portion 123 and the other end of the insulation portion 14 is connected with the second sub-portion 1212, the intermediate portion 123 may be divided into two first sub-portions 1211, a first sub-portion 1211 may subsequently form a first electrode 51 of a transistor, and the second sub-portion 1212 may subsequently form a second electrode 52 of the transistor. As shown in FIGS. 23A and 23B, FIG. 23A is a schematic cross-sectional view along a direction parallel to the base substrate 1 after the word line region groove C1 is formed, and FIG. 23B is a schematic cross-sectional view along a direction aa′ in FIG. 23A. A bottom wall of the word line region groove C1 may be the first insulation thin film, that is, the word line region groove C1 does not expose the base substrate 1. The word line region groove C1 exposes part of a region other than an end portion of each conductive layer 12.

In an exemplary embodiment, one first conductive portion 121 may form a plurality of insulation portions 14, such as two insulation portions 14, wherein both ends of one insulation portion 14 are respectively connected with the intermediate portion 123 and the second sub-portion 1212, and both ends of the other insulation portion 14 are respectively connected with the intermediate portion 123 and a third sub-portion 1213. The intermediate portion 123 may be subsequently divided into two first sub-portions 1211, and the two first sub-portions 1211 may subsequently form first electrodes 51 of two transistors respectively, the second sub-portion 1212 may subsequently form a second electrode 52 of one transistor, and the third sub-portion 1213 may subsequently form a second electrode 52 of another transistor. However, the embodiment of the present disclosure is not limited thereto, and one first conductive portion 121 may form one insulation portion 14.

In an exemplary embodiment, the first insulation thin film between the second sacrificial layer 62 and the first sacrificial layer 61 may be removed from top to bottom of the stacked structure by dry etching, and the first insulation thin film between conductive layers 12 may be laterally removed by wet etching. When the first insulation thin film is etched, the first insulation thin film having a preset thickness at the bottom may be retained without exposing the base substrate 1.

In an exemplary embodiment, the conductive layer 12 may be polysilicon, and the polysilicon is oxidized to form SiO2, that is, the insulation portion 14 may be, but is not limited to, SiO2.

207) The first sacrificial layer 61 and the second sacrificial layer 62 are etched.

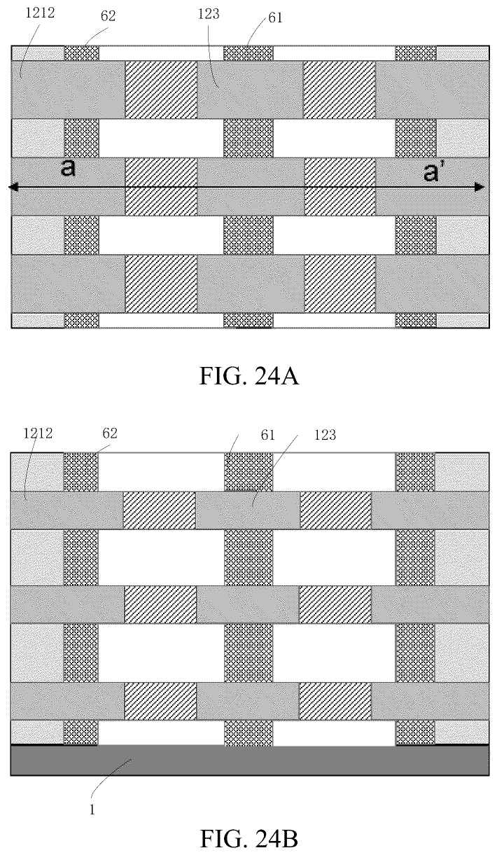

The etching the first sacrificial layer 61 and the second sacrificial layer 62 may include: etching the second sacrificial layer 62 and the first sacrificial layer 61 toward a direction away from the insulation portion 14 to expose a first sub-portion 1211 (here is an intermediate portion 123 composed of two first sub-portions 1211) and a second sub-portion 1212 connected with the insulation portion 14, an etched thickness of the second sacrificial layer 62 is smaller than a thickness of the second sacrificial layer 62 along an etched direction (that is, the direction away from the insulation portion 14), and an etched thickness of the first sacrificial layer 61 is smaller than a thickness of the first sacrificial layer 61 along an etched direction; that is, the second sacrificial layer 62 and the first sacrificial layer 61 are not completely etched away, and a part of the second sacrificial layer 62 and a part of the first sacrificial layer 61 are retained, as shown in FIGS. 24A and 24B, wherein FIG. 24A is a schematic cross-sectional view along a direction parallel to the base substrate 1 after the second sacrificial layer 62 and the first sacrificial layer 61 are etched, and FIG. 24B is a schematic cross-sectional view along a direction aa′ in FIG. 24A.

In an exemplary embodiment, the first sacrificial layer 61 and the second sacrificial layer 62 may be etched by wet etching, and a solution having a relatively large selective ratio of the insulation portion 14, the first sacrificial layer 61, and the second sacrificial layer 62 may be selected for etching. For example, when a material of the insulation portion 14 is SiO2 and a material of the first sacrificial layer 61 and the second sacrificial layer 62 is SiN, an acid solution (such as phosphoric acid) having a relatively large selective ratio of SiO2 and SiN is used to etch laterally a SiN thin film between layers toward both sides away from the insulation portion 14.

208) A semiconductor layer 23, a gate insulation layer 24, and a gate electrode 26 are formed.

The forming the semiconductor layer 23, the gate insulation layer 24, and the gate electrode 26 may include: sequentially depositing a semiconductor thin film, a gate insulation film, and a gate electrode thin film on the base substrate 1 on which the aforementioned structure is formed to form the semiconductor layer 23, the gate insulation layer 24, and the gate electrode 26 respectively; wherein the semiconductor layer 23 covers the insulation portion 14, covers an exposed region of the first sub-portion 1211 (here, it refers to an exposed region of one end of the intermediate portion 123 facing the insulation portion 14), covers an exposed region of the second sub-portion 1212, and covers sidewalls of the second sacrificial layer 62 and the first sacrificial layer 61. Gate electrodes 26 of transistors in a same layer and in a same column are connected to form a word line 40. There is a gap between word lines 40 of different layers.

A distance between first conductive portions 121 of a same conductive layer 12 and a distance between different conductive layers 12 may be controlled, so that gate electrodes 26 of transistors in a same layer and in a same column are connected with each other to form the word line 40 when a gate electrode thin film is deposited; and, there is a gap between gate electrodes 26 of transistors of different layers.

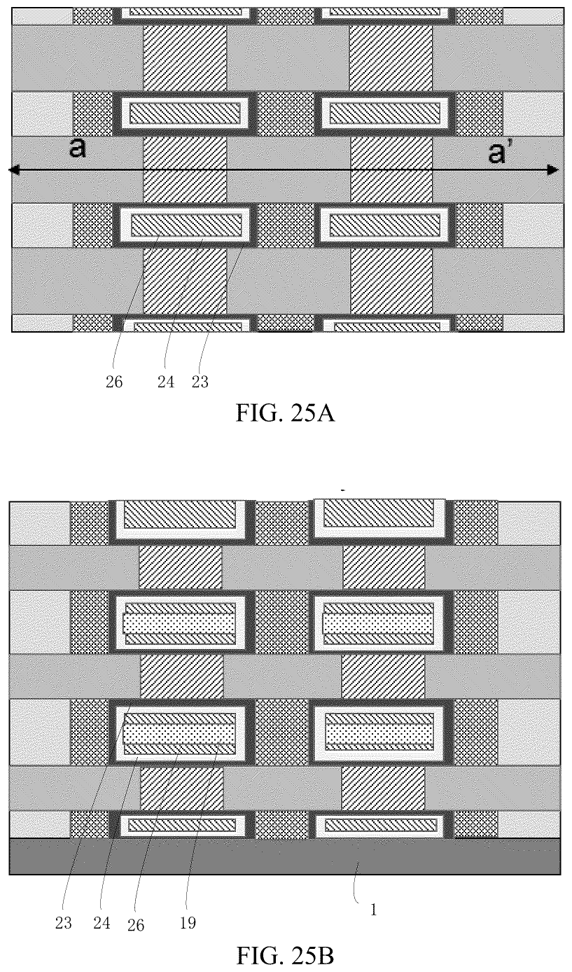

A sixth insulation thin film is deposited to form a sixth insulation layer 19, and word lines 40 of different layers are isolated from each other through the sixth insulation layer 19, as shown in FIGS. 25A and 25B. FIG. 25A is a schematic cross-sectional view in a direction parallel to the base substrate 1 after the semiconductor layer 23, the gate insulation layer 24, and the gate electrode 26 are formed; FIG. 25B is a schematic cross-sectional view along a direction aa′ in FIG. 25A.

In an exemplary embodiment, the semiconductor thin film includes, but is not limited to, Indium Gallium Zinc Oxide (IGZO), Indium Tin Oxide (ITO), Indium Zinc Oxide (IZO), and the like. When IGZO is used as a semiconductor layer, it has advantages of low leakage and short refresh time.

In an exemplary embodiment, the gate insulation thin film may be a High-K material, including but not limited to Aluminum Oxide (Al2O3), Hafnium dioxide (HfO2), and the like.

In an exemplary embodiment, the gate electrode thin film includes, but is not limited to, titanium nitride/tungsten (a stacked structure composed of TiN/W) or a transparent conductive oxide thin film, and the transparent conductive oxide thin film includes, but is not limited to, ITO, Aluminum-doped Zinc Oxide (AZO), IZO, and the like.

In an exemplary embodiment, the sixth insulation thin film may be a low-K material.

In an exemplary embodiment, the semiconductor thin film, the gate insulation thin film, the gate electrode thin film, and the sixth insulation thin film may be deposited through an ALD manner.

209) A bit line 30 is formed.

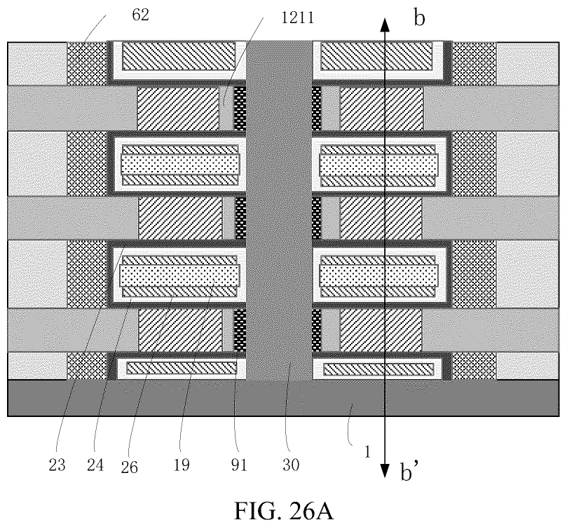

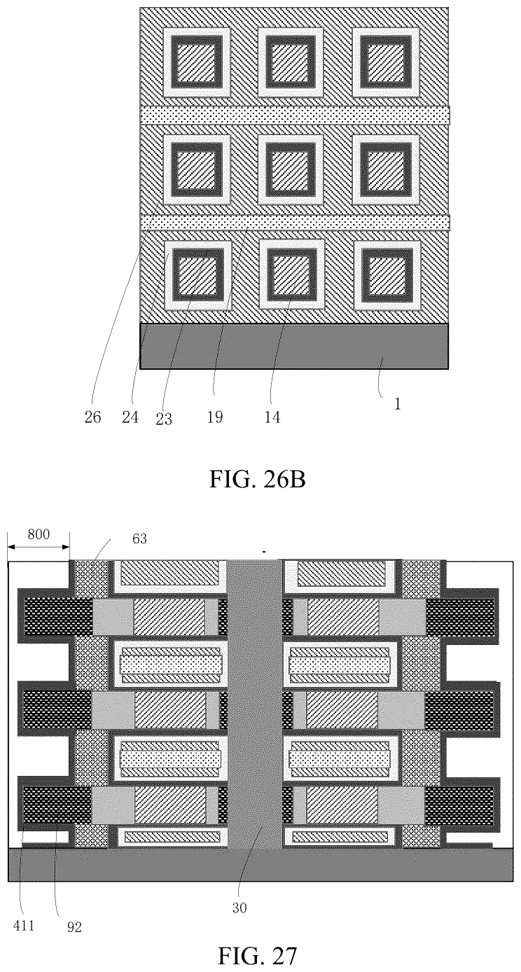

The forming the bit line 30 may include:
removing the first sacrificial layer 61 by etching, and removing the semiconductor layer 23 covering a sidewall of the first sacrificial layer 61 by etching so that semiconductor layers 23 of transistors of different layers are disconnected from each other on a side close to a bit line so as to subsequently eliminate a parasitic transistor, at this time, the semiconductor layer 23 covers the insulation portion 14, covers an exposed region of the first sub-portion 1211 (here, it refers to an exposed region of one end of the intermediate portion 123 facing the insulation portion 14), covers an exposed region of the second sub-portion 1212, and covers a sidewall of the second sacrificial layer 62;
depositing a seventh insulation thin film on the base substrate 1 on which the abovementioned structure is formed to form a seventh insulation layer, wherein the seventh insulation layer fills a region where the first sacrificial layer 61 is located and a region where the semiconductor layer 23 covers the sidewall of the first sacrificial layer 61 is located;
forming a plurality of fourth vias K4 penetrating a stacked structure formed by the seventh insulation layer and the conductive layer 12; wherein the plurality of fourth vias K4 may divide the intermediate portion 123 into two independent first sub-portions 1211, and a sidewall of a fourth via K4 exposes the first sub-portion 1211;
depositing a metal on an exposed surface of the first sub-portion 1211 to form a first connection layer 91 to reduce a contact resistance;
depositing a third conductive thin film filling the fourth vias K4 in the plurality of fourth vias K4 to form a plurality of bit lines 30 respectively, as shown in FIGS. 26A and 26B, wherein FIG. 26A is a schematic cross-sectional view along a direction aa′ after the bit lines 30 are formed, and FIG. 26B is a schematic cross-sectional view along a direction bb′ in FIG. 26A.

In an exemplary embodiment, the seventh insulation thin film may be a low-K material.

In an exemplary embodiment, the deposited metal may include, but is not limited to, deposited Titanium (Ti), Cobalt (Co), Nickel Platinum (NiPt), and the like, and the first connection layer 91 may include, but is not limited to, Titanium disilicide (TiSi2), Cobalt disilicide (CoSi2), Nickel Platinum Silicide (NiPtSi), and the like.

In an exemplary embodiment, the third conductive thin film may have a multilayer structure including Ti/TiN/W or the like. The deposition of the third conductive thin film may be sequential deposition of Ti, TiN, W, or the like.

In an exemplary embodiment, cross sections of the bit lines 30 may be square, circular, or other shapes along a direction parallel to the base substrate 1.

210) A first plate 41 is formed.

The forming the first plate 41 may include:
removing a first insulation thin film of a capacitance region 800 to expose part of a region of the second sub-portion 1212;
depositing a metal on a surface of the exposed region of the second sub-portion 1212 to form a second connection layer 92 to reduce resistance; and
sequentially depositing an adhesive layer thin film on the base substrate 1 on which the aforementioned structure is formed, and forming an adhesive layer 411 covering the sidewall of the second sacrificial layer 62 on a side away from a bit line 30 and covering a surface of a metal silicide located in the capacitance region 800, wherein the adhesive layer 411 and the second connection layer 92 constitute a first plate 41 of a capacitor; as shown in FIG. 27, FIG. 27 is a schematic cross-sectional view along a direction aa′ after the first plate 41 is formed.

In an exemplary embodiment, the adhesive layer thin film may be TiN.

In an exemplary embodiment, the deposited metal may be deposited Titanium (Ti), Cobalt (Co), Nickel Platinum (NiPt), or the like, and the metal silicide may be Titanium disilicide (TiSi2), Cobalt disilicide (CoSi2), Nickel Platinum Silicide (NiPtSi), or the like.

211) A dielectric layer 13 and a second plate 42 are formed.

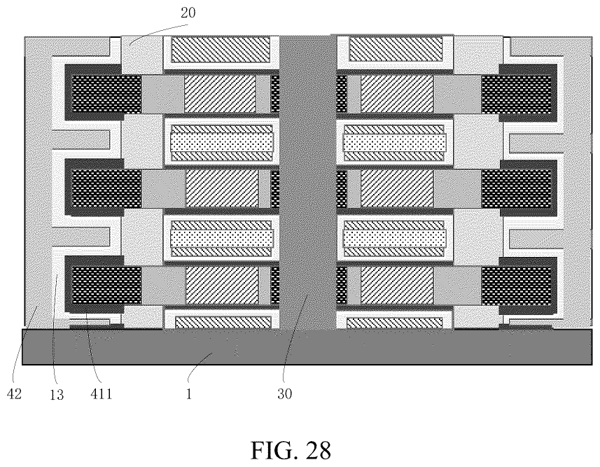

The forming the dielectric layer 13 and the second plate 42 may include: removing the second sacrificial layer 62 by etching; and etching and removing the adhesive layer 411 covering one sidewall of the second sacrificial layer 62 and the semiconductor layer 23 covering the other sidewall of the second sacrificial layer 62; so that the adhesive layer 411 is disconnected to avoid connections of first plates 41 of different devices, and semiconductor layers 23 of transistors of different layers are disconnected to eliminate a parasitic transistor;
depositing an eighth insulation thin film on the base substrate 1 on which the abovementioned structure is formed to form an eighth insulation layer 20, wherein the eighth insulation layer 20 fills a region where the second sacrificial layer 62 is located, a region where a portion of the adhesive layer 411 is etched, and a region where a portion of the semiconductor layer 23 is etched;
depositing a dielectric thin film on the base substrate 1 on which the abovementioned structure is formed to form a dielectric layer 13, wherein the dielectric layer 13 covers a surface of the first plate 41 on a side away from the bit line 30;
depositing a conductor material on the base substrate 1 on which the aforementioned structure is formed to form a second plate 42, wherein the second plate 42 covers a surface of the dielectric layer 13 on a side away from the bit line 30, as shown in FIG. 28, wherein FIG. 28 is a schematic cross-sectional view along a direction aa′ after the dielectric layer 13 and the second plate 42 are formed.

In an exemplary embodiment, the adhesive layer 411 may not be provided.

In an exemplary embodiment, the eighth insulation thin film may be a low-K dielectric material, that is, a dielectric material having a dielectric constant K<3.9, including but not limited to silicon oxide such as Silicon dioxide (SiO2).

In an exemplary embodiment, the conductor material may be polysilicon, TiN, W, or the like.

In an exemplary embodiment, the second sacrificial layer 62 may be etched and removed after the adhesive layer 411 is formed; and the dielectric layer 13 is formed before etching and removing the adhesive layer 411 covering one sidewall of the second sacrificial layer 62 and the semiconductor layer 23 covering the other sidewall of the second sacrificial layer 62.

An embodiment of the present disclosure also provides an electronic device including the 3D stacked semiconductor device of the foregoing embodiments. The electronic apparatus may be a storage device, a smart phone, a computer, a tablet computer, an artificial intelligence device, a wearable device or a mobile power supply, etc. The storage device may include a memory in a computer or the like, which is not limited here.

An embodiment of the present disclosure provides a method for manufacturing a 3D stacked semiconductor device, the 3D stacked semiconductor device includes a plurality of transistors stacked along a direction perpendicular to a base substrate and distributed in different layers, and the method for manufacturing the 3D stacked semiconductor device may include:
providing a base substrate, wherein a first insulation thin film and a first conductive thin film are sequentially and alternately deposited on the base substrate and are patterned to form a stacked structure, the stacked structure includes a stack of first insulation layers and conductive layers which are alternately disposed, and the conductive layer includes a first conductive portion;
forming a first sacrificial layer, a second sacrificial layer, and a word line region groove, wherein the word line region groove exposes part of a region other than an end portion of each first conductive portion, and the first sacrificial layer and the second sacrificial layer constitute sidewalls of the word line region groove;
performing insulation treatment on a conductive layer located in the word line region groove to form an insulation portion, wherein the first conductive portion is partitioned by the insulation portion to form a first sub-portion and a second sub-portion which are independent; etching the first sacrificial layer and the second sacrificial layer toward a direction away from the insulation portion to expose the conductive layer connected with the insulation portion, an etched thickness of the first sacrificial layer is smaller than a thickness of the first sacrificial layer along an etched direction, and an etched thickness of the second sacrificial layer is smaller than a thickness of the second sacrificial layer along an etched direction;
sequentially depositing a semiconductor thin film, a gate insulation thin film, and a gate electrode thin film on the base substrate to form a semiconductor layer, a gate insulation layer and a gate electrode of the transistor respectively, wherein the semiconductor layer surrounds the first sub-portion, the second sub-portion, and the insulation portion, and the gate electrode surrounds a sidewall of the semiconductor layer; and
performing a resistance reduction treatment on the first sub-portion and the second sub-portion to form a first electrode and a second electrode of the transistor respectively.

In an exemplary embodiment, the manufacturing method may further include:
removing the first sacrificial layer and the second sacrificial layer by etching, and removing semiconductor layers covering the first sacrificial layer and the second sacrificial layer by etching to disconnect semiconductor layers of transistors of different layers.

In an exemplary embodiment, the performing insulation treatment on the conductive layer located in the word line region groove to form the insulation portion includes: oxidizing the conductive layer located in the word line region groove to form the insulation portion;
performing the resistance reduction treatment on the first sub-portion and the second sub-portion includes:
exposing at least part of a region of the first sub-portion and at least part of a region of the second sub-portion, and performing a metal silicidation treatment on the exposed region of the first sub-portion and the exposed region of the second sub-portion to form a metal silicide.

In an exemplary embodiment, when the gate electrode thin film is deposited, gate electrodes of the plurality of transistors are made be connected to form a word line;

The conductive layer further includes a second conductive portion; the manufacturing method further includes: performing a resistance reduction treatment on the second conductive portion to form a bit line.

In an exemplary embodiment, the manufacturing method may further include:
forming a via penetrating through the stacked structure, wherein a sidewall of the via exposes each first sub-portion;
depositing a conductive thin film filling the via in the via to form a bit line.

The method for manufacturing the 3D stacked semiconductor device according to the embodiment of the present disclosure may form a first electrode, a second electrode, and an insulation portion before an insulation treatment at one time, has a simple process, facilitates stacking, and may improve an integration level.

Although implementations disclosed in the present invention are as the above, the described contents are only implementations used for facilitating understanding the present invention, and are not intended to limit the present disclosure. Any person skilled in the art to which the present disclosure pertains may make any modification and variation in the form and details of implementations without facing away from the spirit and the scope disclosed in the present disclosure. Nevertheless, the scope of patent protection of the present disclosure shall still be subject to the scope defined by the appended claims.

1. A 3D stacked semiconductor device, comprising:
a plurality of transistors distributed in different layers and stacked along a direction perpendicular to a base substrate;
a transistor of the plurality of transistors comprises a first electrode, a second electrode, an insulation portion connecting the first electrode and the second electrode, a semiconductor layer surrounding the first electrode, the insulation portion, and the second electrode, a gate electrode surrounding a sidewall of the semiconductor layer, a gate insulation layer disposed between the gate electrode and the semiconductor layer, and the first electrode, the insulation portion, and the second electrode are connected to form an integral structure.

2. The 3D stacked semiconductor device of claim 1, wherein the first electrode, the insulation portion, and the second electrode extend along a direction parallel to the base substrate.

3. The 3D stacked semiconductor device of claim 1, wherein the first electrode comprises a first sub-portion and a first connection layer surrounding the first sub-portion, the semiconductor layer surrounds the first sub-portion and is in contact with the first sub-portion, the second electrode comprises a second sub-portion and a second connection layer surrounding the second sub-portion, the semiconductor layer surrounds the second sub-portion and is in contact with the second sub-portion, on a plane parallel to the base substrate, an orthographic projection of the first connection layer is outside an orthographic projection of the semiconductor layer, and an orthographic projection of the second connection layer is outside the orthographic projection of the semiconductor layer; the insulation portion is in contact with the first sub-portion and the second sub-portion.

4. The 3D stacked semiconductor device of claim 1, wherein semiconductor layers of transistors of different layers are disconnected.

5. The 3D stacked semiconductor device of claim 1, wherein the semiconductor layer extends along a direction parallel to the base substrate.

6. The 3D stacked semiconductor device of claim 1, further comprising: a word line extending along the direction perpendicular to the base substrate; wherein a gate electrode of each of the transistors is part of the word line.

7. The 3D stacked semiconductor device of claim 6, further comprising: a plurality of bit lines extending along a direction parallel to the base substrate and distributed in different layers, wherein a bit line of the plurality of bit lines and a first electrode of a transistor in a same layer as the bit line are connected to form an integral structure.

8. The 3D stacked semiconductor device of claim 7, further comprising: a plurality of vias, and a plurality of connection electrodes filling the plurality of vias respectively, wherein a bottom wall of each via exposes one bit line, and a sidewall of the via exposes a bit line through which the via penetrates, and a bit line isolation layer is disposed between a connection electrode of the plurality of connection electrodes and a bit line exposed by a sidewall of a via where the connection electrode is located.

9. The 3D stacked semiconductor device of claim 1, wherein gate insulation layers of transistors of different layers are connected to be of an integral structure.

10. The 3D stacked semiconductor device of claim 1, wherein the first electrode comprises a first sub-portion and a first connection layer surrounding the first sub-portion, the semiconductor layer surrounds the first sub-portion and the first connection layer and is in contact with the first sub-portion and the first connection layer, the second electrode comprises a second sub-portion and a second connection layer surrounding the second sub-portion, the semiconductor layer surrounds the second sub-portion and is in contact with the second sub-portion, on a plane parallel to the base substrate, an orthographic projection of the second connection layer is outside an orthographic projection of the semiconductor layer, and an orthographic projection of the first connection layer is overlapped with the orthographic projection of the semiconductor layer; the insulation portion is in contact with the first sub-portion and the second sub-portion.

11. The 3D stacked semiconductor device of claim 3, wherein the first sub-portion and the second sub-portion comprise polysilicon, and the first connection layer and the second connection layer comprise a metal silicide.

12. The 3D stacked semiconductor device of claim 1, further comprising: a plurality of word lines distributed in different layers and extending along a direction parallel to the base substrate; wherein the gate electrode of the transistor is a part of a word line in a same layer.

13. The 3D stacked semiconductor device of claim 12, further comprising: a bit line extending along the direction perpendicular to the base substrate; wherein first electrodes of the plurality of transistors are connected to a same bit line.

14. An electronic device comprising a 3D stacked semiconductor device of claim 1.

15. A method for manufacturing a 3D stacked semiconductor device, wherein the 3D stacked semiconductor device comprises a plurality of transistors stacked along a direction perpendicular to a base substrate and distributed in different layers, and the method for manufacturing the 3D stacked semiconductor device comprises:
providing the base substrate, and sequentially and alternately depositing a first insulation thin film and a first conductive thin film on the base substrate and patterning the first insulation thin film and the first conductive thin film to form a stacked structure, wherein the stacked structure comprises a stack of first insulation layers and conductive layers which are alternately disposed, and a conductive layer of the conductive layers comprises a first conductive portion;
forming a first sacrificial layer, a second sacrificial layer, and a word line region groove, wherein the word line region groove exposes part of a region other than an end portion of each first conductive portion, and the first sacrificial layer and the second sacrificial layer constitute sidewalls of the word line region groove;
performing insulation treatment on a conductive layer located in the word line region groove to form an insulation portion, wherein the first conductive portion is partitioned by the insulation portion to form a first sub-portion and a second sub-portion which are independent; etching the first sacrificial layer and the second sacrificial layer toward a direction away from the insulation portion to expose the conductive layer connected with the insulation portion, an etched thickness of the first sacrificial layer is smaller than a thickness of the first sacrificial layer along an etched direction, and an etched thickness of the second sacrificial layer is smaller than a thickness of the second sacrificial layer along the etched direction;
sequentially depositing a semiconductor thin film, a gate insulation thin film, and a gate electrode thin film on the base substrate to form a semiconductor layer, a gate insulation layer and a gate electrode of a transistor of the plurality of transistors respectively, wherein the semiconductor layer surrounds the first sub-portion, the second sub-portion, and the insulation portion, and the gate electrode surrounds a sidewall of the semiconductor layer; and
performing a resistance reduction treatment on the first sub-portion and the second sub-portion to form a first electrode and a second electrode of the transistor respectively.

16. The method for manufacturing the 3D stacked semiconductor device of claim 15, further comprising:
removing the first sacrificial layer and the second sacrificial layer by etching, and removing semiconductor layers covering the first sacrificial layer and the second sacrificial layer by etching to disconnect semiconductor layers of transistors of different layers.

17. The method for manufacturing the 3D stacked semiconductor device of claim 15, wherein
the performing the insulation treatment on the conductive layer located in the word line region groove to form the insulation portion comprises: oxidizing the conductive layer located in the word line region groove to form the insulation portion;
the performing the resistance reduction treatment on the first sub-portion and the second sub-portion comprises:
exposing at least part of a region of the first sub-portion and at least part of a region of the second sub-portion, and performing a metal silicidation treatment on the exposed region of the first sub-portion and the exposed region of the second sub-portion to form a metal silicide.

18. The method for manufacturing the 3D stacked semiconductor device of claim 15, wherein when the gate electrode thin film is deposited, gate electrodes of the plurality of transistors are made be connected to form a word line;
the conductive layer further comprises a second conductive portion; the method further comprises: performing a resistance reduction treatment on the second conductive portion to form a bit line.

19. The method for manufacturing the 3D stacked semiconductor device of claim 15, wherein the method further comprises:
forming a via penetrating through the stacked structure, wherein a sidewall of the via exposes each first sub-portion; and
depositing a conductive thin film filling the via in the via to form a bit line.

20. The 3D stacked semiconductor device of claim 2, wherein gate insulation layers of transistors of different layers are connected to be of an integral structure.
